(19) United States
(12) Patent Application Publication
(10) Pub. No.: US 2019/0025699 A1
(43) Pub. Date: Jan. 24, 2019

(54) FILM-FORMING MATERIAL FOR RESIST PROCESS AND PATTERN-FORMING METHOD

(71) Applicant: JSR CORPORATION, Tokyo (JP)

(72) Inventors: Junya Suzuki, Tokyo (JP); Tomoaki Seko, Tokyo (JP); Yusuke Anno, Tokyo (JP)

(73) Assignee: JSR CORPORATION, Tokyo (JP)

(21) Appl. No.: 16/142,242

(22) Filed: Sep. 26, 2018

Related U.S. Application Data
(63) Continuation of application No. PCT/JP2017/008113, filed on Mar. 1, 2017.

(30) Foreign Application Priority Data
Mar. 30, 2016 (JP) 2016-068469

(51) Int. Cl. G03F 7/11; G03F 7/09; C09D 183/04; G03F 7/16; H01L 21/308

(52) U.S. Cl. CPC G03F 7/11; G03F 7/094; C09D 183/04; H01L 21/3086; G03F 7/168; H01L 21/3081; G03F 7/162

(57) ABSTRACT

A film-forming material for a resist process includes: a siloxane polymer component including at least two selected from the group consisting of a sulfur atom, a nitrogen atom, a boron atom and a phosphorus atom; and organic solvent. The siloxane polymer component preferably has a formulation represented by formula (1). R¹ represents a monovalent organic group comprising at least one of a sulfur atom and a nitrogen atom. R² represents a monovalent organic group comprising at least one of a sulfur atom and a nitrogen atom, a hydrogen atom, a hydroxy group, or a substituted or unsubstituted hydrocarbon group having 1 to 20 carbon atoms. A pattern-forming method includes: applying the film-forming material for a resist process onto a substrate to form a silicon-containing film; forming a pattern using the silicon-containing film as a mask; and removing the silicon-containing film.

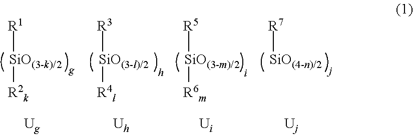

The present application is a continuation application of International Application No. PCT/JP2017/008113, filed Mar. 1, 2017, which claims priority to Japanese Patent Application No. 2016-068469, filed Mar. 30, 2016. The contents of these applications are incorporated herein by reference in their entirety.

### BACKGROUND OF THE INVENTION

### Field of the Invention

The present invention relates to a film-forming material for a resist process, and a pattern-forming method.

### DISCUSSION OF THE BACKGROUND

In pattern formation of elements for semiconductors and the like, a resist process is performed in which a resist film laminated via an organic resist underlayer film on a substrate to is exposed and developed, and then a resulting resist pattern is used as a mask for etching, whereby microfabrication of the substrate is accomplished.

The difference in etching rate is small between the resist film and the organic resist underlayer film. Therefore, microfabrication and film-thinning of resist films are accompanied by inconvenience of failure in microfabrication of a substrate to be processed which has been coated with an organic resist underlayer film, when the etching is conducted using the resist pattern as a mask. Thus, a multilayer resist process has been employed in which a silicon-containing film is provided between the resist film and the organic resist underlayer film (see PCT International Publication No. 2006-126406).

As microfabrication of patterns proceeds, resist films and silicon-containing films need to be thinner, with increasing demands for various performances such as an antireflective property and etching resistance of the silicon-containing films. In addition, since the silicon-containing film used as the mask remains on the substrate to be processed after the etching, eliminating the residues from the substrate surface is necessary. Also, when defects are generated in patterning the silicon-containing film and/or the resist film in practically employed production processes of a semiconductor element, etc., reprocessing may be carried out.

Proposed methods for removing a silicon-containing film involve: a wet removal method including: treating with an acidic removal liquid containing a sulfuric acid ion and/or fluorine ion, followed by treating with an alkaline removal liquid (see Japanese Unexamined Patent Application, Publication No. 2010-139764); a wet removal composition containing a fluoride source and an ammonium salt (see Japanese Unexamined Patent Application (Translation of PCT Application), Publication No. 2010-515107); wet removal with aqueous hydrogen fluoride of high concentration, as well as dry removal (see Japanese Unexamined Patent Application, Publication No. 2010-85912); and the like.

### SUMMARY OF THE INVENTION

According to an aspect of the present invention, a film-forming material for a resist process includes a siloxane polymer component and an organic solvent. The siloxane polymer component includes at least two selected from a sulfur atom, a nitrogen atom, a boron atom, a phosphorus atom and a combination thereof.

According another aspect of the present invention, a pattern-forming method includes: applying the film-forming material for a resist process onto a substrate to form a silicon-containing film; forming a pattern using the silicon-containing film as a mask; and removing the silicon-containing film.

### DESCRIPTION OF EMBODIMENTS

According to one embodiment of the present invention, a film-forming material for a resist process includes: a siloxane polymer component including at least two selected from a sulfur atom, a nitrogen atom, a boron atom, a phosphorus atom and a combination thereof; and an organic solvent.

According to another embodiment of the invention, a pattern-forming method includes: applying the film-forming material for a resist process according to the one embodiment onto a substrate to form a silicon-containing film; forming a pattern using the silicon-containing film as a mask; and removing the silicon-containing film.

The film-forming material for a resist process according to the one embodiment of the present invention is capable of forming a silicon-containing film that is superior in CF₄ gas etching easiness, and also superior in oxygen gas etching resistance. Also, the film-forming material for a resist process according to the one embodiment of the present invention is capable of forming a silicon-containing film that exhibits removability with an acidic liquid, etching easiness for CF₄ gas and etching resistance against oxygen gas each being favorable in a well-harmonized manner. Furthermore, the film-forming material for a resist process according to the one embodiment of the present invention is also capable of forming a silicon-containing film having reduced substrate reflectance, also with superior solvent resistance. Moreover, the film-forming material for a resist process of the one embodiment of the present invention can be used in a multilayer resist process, a reversal pattern formation process and the like.

The pattern-forming method of another embodiment of the present invention enables a superior resist pattern to be formed by using a superior silicon-containing film formed from the film-forming material for a resist process of the one embodiment.

Therefore, these can be suitably used for manufacture, etc., of semiconductor devices in which further progress of microfabrication is expected in the future.

Hereinafter, embodiments for putting into practice the film-forming material for a resist process and the pattern-forming method of the present invention will be described.

### Film-Forming Material for Resist Process

The film-forming material for a resist process (hereinafter, may be also merely referred to as “film-forming material”) according to one embodiment of the present invention contains: (A) a siloxane polymer component including at least two selected from the group consisting of a sulfur atom, a nitrogen atom, a boron atom and a phosphorus atom; and (B) an organic solvent.

The film-forming material may contain optional components such as (C) an additive, (D) a crosslinking agent and (E) water, within a range not leading to impairment of the effects of the present invention. Each component is described below in detail.

### (A) Polymer Component

The polymer component (A) is preferably a siloxane polymer component including a sulfur atom and a nitrogen atom. The polymer component (A) may be constituted from one type of a polymer, or may be a mixture of two or more types of polymers.

Modes of the polymer component (A) are exemplified by:

1) a siloxane polymer that includes a structural unit having both a sulfur atom and a nitrogen atom;

2) a siloxane polymer that includes both a structural unit having a sulfur atom, and a structural unit having a nitrogen atom; and

3) a mixture of a siloxane polymer that includes a structural unit having a sulfur atom, and a siloxane polymer that includes a structural unit having a nitrogen atom. Alternatively, a mixture of a siloxane polymer that includes a structural unit having both a sulfur atom and a nitrogen atom, and a siloxane polymer that includes a structural unit having only one of a sulfur atom and a nitrogen atom.

The polymer component (A) is exemplified by a polymer having a formulation represented by the following formula (1).

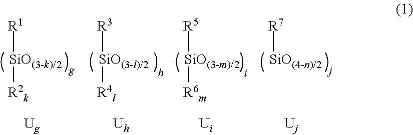

In the formula (1),

R¹ represents a monovalent organic group including only one of a sulfur atom and a nitrogen atom, or a monovalent organic group including a sulfur atom and a nitrogen atom;

R² represents a monovalent organic group including only one of a sulfur atom and a nitrogen atom, a monovalent organic group including a sulfur atom and a nitrogen atom, or a hydrogen atom, a hydroxy group, or a substituted or unsubstituted hydrocarbon group having 1 to 20 carbon atoms; k is 0 or 1.

R³ represents a monovalent organic group including an ethylenic unsaturated double bond;

R⁴ represents a monovalent organic group having an ethylenic unsaturated double bond, or a hydrogen atom, a hydroxy group, or a substituted or unsubstituted hydrocarbon group having 1 to 20 carbon atoms;

1 is 0 or 1;

R⁵ represents a non-crosslinkable monovalent organic group having a photoabsorptive group including neither a sulfur atom nor a nitrogen atom;

R⁶ represents a non-crosslinkable monovalent organic group having a photoabsorptive group including neither a sulfur atom nor a nitrogen atom, or a hydrogen atom, a hydroxy group, or a substituted or unsubstituted non-crosslinkable monovalent hydrocarbon group having 1 to 20 carbon atoms;

m is 0 or 1;

R⁷ represents a substituted or unsubstituted non-crosslinkable and non-photoabsorptive monovalent aliphatic hydrocarbon group including neither a sulfur atom nor a nitrogen atom, or a substituted or unsubstituted non-crosslinkable and non-photoabsorptive monovalent alicyclic hydrocarbon group including neither a sulfur atom nor a nitrogen atom; n is an integer of 0 to 2;

g denotes a mole fraction of a structural unit U_{g} with respect to total structural units included in the siloxane polymer component;

h denotes a mole fraction of a structural unit Uₕ with respect to total structural units included in the siloxane polymer component;

I denotes a mole fraction of a structural unit Uᵢ with respect to total structural units included in the siloxane polymer component;

j denotes a mole fraction of a structural unit Uⱼ with respect to total structural units included in the siloxane polymer component;

inequalities: 0<g<1; 0≤h<1; 0≤i<1; 0≤j<1; and g+h+i+j≤1 are satisfied, and

in a case in which the siloxane polymer component does not include as the structural unit U_{g}, a structural unit U_{g1}, wherein R¹ or R² represents a monovalent organic group including a sulfur atom and a nitrogen atom, the siloxane polymer component includes as the structural unit U_{g}, a structural unit U_{g2}, or both a structural unit U_{g3-1} and a structural unit U_{g3-2}:
in the structural unit U_{g2}, k is 1; R¹ represents a monovalent organic group including a sulfur atom and no nitrogen atom; and R² represents a monovalent organic group including a nitrogen atom and no sulfur atom;
in the structural unit U_{g3-1}, R¹ represents a monovalent organic group including a sulfur atom and no nitrogen atom, wherein in a case in which k is 1, R² represents a group other than a monovalent organic group including a nitrogen atom; and
in the structural unit U_{g3-2}, R¹ represents a monovalent organic group including a nitrogen atom and no sulfur atom, wherein in a case in which k is 1, R² represents a group other than a monovalent organic group including a sulfur atom.

It is to be noted that the structural unit U_{g2} has, of the sulfur atom and the nitrogen atom: an organic group including only the sulfur atom; and an organic group including only the nitrogen atom. The structural unit U_{g3-1} has only the sulfur atom of the sulfur atom and the nitrogen atom. The structural unit U_{g3-2} has only the nitrogen atom of the sulfur atom and the nitrogen atom.

The siloxane polymer component may further have a structural unit Uₕ in addition to the structural unit U_{g}. In other words, in the above formula (1), the inequalities: 0<g<1 and 0<h<1 may be satisfied.

Since an ethylenic unsaturated double bond is included owing to further having the structural unit Uₕ the siloxane polymer component enables solvent resistance of the silicon-containing film to be improved, and also enables removability with an acidic liquid to be improved.

The siloxane polymer component may further have a structural unit Uᵢ in addition to the structural unit U_{g} and the structural unit Uₕ. In other words, in the above formula (1), the inequalities: 0<g<1 and 0<i<1 may be satisfied.

Since a photoabsorptive group is included owing to further having the structural unit Uᵢ, the siloxane polymer component enables substrate reflectance to be decreased, thereby enabling a favorable resist pattern to be obtained.

The siloxane polymer component may further have a structural unit Uⱼ in addition to the structural unit U_{g}, the structural unit Uₕ and the structural unit Uᵢ. In other words, in the above formula (1), the inequalities: 0<g<1 and 0<j<1 may be satisfied.

Owing to the siloxane polymer component further having the structural unit Uⱼ, the proportion of silicon included in the polymer increases, thereby enabling oxygen gas etching resistance to be improved.

The siloxane polymer component may have at least two structural units among the structural unit Uₕ, the structural unit Uᵢ and the structural unit Uⱼ.

In the following, each structural unit represented by the above formula (1) is described.

Structural Unit U_{g}

In the structural unit U_{g} in the above formula (1), R¹ represents a monovalent organic group including only one of a sulfur atom and a nitrogen atom, or a monovalent organic group including a sulfur atom and a nitrogen atom.

Meanwhile, R² represents a monovalent organic group including only one of a sulfur atom and a nitrogen atom, a monovalent organic group including a sulfur atom and a nitrogen atom, a hydrogen atom, a hydroxy group, or a substituted or unsubstituted hydrocarbon group having 1 to 20 carbon atoms.

In the above formula (1), the structural unit U_{g} consists of each structural unit including at least one of the sulfur atom and the nitrogen atom, and as a whole, the structural unit U_{g} includes both the sulfur atom and the nitrogen atom. The structural unit U_{g} may be constituted from a single structural unit including both the sulfur atom and the nitrogen atom in one structural unit, or may be constituted from a structural unit including the sulfur atom and a structural unit including the nitrogen atom. The structural unit including both the sulfur atom and the nitrogen atom in one structural unit U_{g} is exemplified by the structural unit U_{g1} and the structural unit U_{g2}. The structural unit U_{g} constituted from a structural unit including the sulfur atom and a structural unit including the nitrogen atom is exemplified by a structural unit that includes the structural unit U_{g3-1} and the structural unit U_{g3-2}.

The monovalent organic group including only one of a sulfur atom and a nitrogen atom is exemplified by:

monovalent organic groups having a sulfur atom-containing group such as a sulfide group (—S—), a polysulfide group, a sulfoxide group (—SO—), a sulfonyl group (—SO₂—) or a sulfanyl group (—SH); and

monovalent organic groups having a nitrogen atom-containing group such as a cyano group, an isocyanate group, an amino group or an amide group.

Examples of the monovalent organic group including a sulfur atom and a nitrogen atom include:

monovalent organic groups having a thiocyanate group (—SCN), an isothiocyanate group (—NSC) or a thioisocyanate group (—NCS);

monovalent organic groups having the sulfur atom-containing group and the nitrogen atom-containing group;

monovalent organic groups having at least two selected from the group consisting of a thiocyanate group, an isothiocyanate group, a thioisocyanate group, the sulfur atom-containing group, and the nitrogen atom-containing group; and the like.

R¹ and R² preferably include a sulfide group, a polysulfide group, a sulfoxide group, a sulfonyl group, a sulfanyl group, a cyano group, a thiocyanate group, an isothiocyanate group, a thioisocyanate group or a combination thereof. Furthermore, as R¹ and R², a group including a thioisocyanate group; a group including a sulfide group and a cyano group; a group including a cyano group; and a group including a sulfanyl group are preferred. Alternatively, R¹ and R² represent preferably a group constituted from these groups and a hydrocarbon group.

The number of carbon atoms in each of R¹ and R², in particular, the number of carbon atoms constituting the monovalent organic group including only one of a sulfur atom and a nitrogen atom, or constituting the monovalent organic group including a sulfur atom and a nitrogen atom is preferably 1 to 6, more preferably 1 to 4, and particularly preferably 1 or 2.

Specifically, as R¹ and R², groups represented by the following formulae (2) to (4) are preferred, and a group represented by the formula (2) is more preferred.

—R^{a}—S—R^{b}—CN (2)

—R^{c}—SH (3)

—R^{d}—CN (4)

In the above formulae (2) to (4), R^{a}, R^{b}, R^{C} and R^{d} each independently represent a single bond or an alkanediyl group having 1 to 5 carbon atoms.

The alkanediyl group having 1 to 5 carbon atoms is exemplified by a group represented by —(CH₂)ₙ— (wherein, n is an integer of 1 to 5), as well as an ethane-1,1-diyl group, a propane-2,2-diyl group and the like, and the group represented by —(CH₂)ₙ— is preferred.

R^{a} represents preferably an alkanediyl group having 1 to 3 carbon atoms, and more preferably a methanediyl group.

R^{b} represents preferably a single bond or an alkanediyl group having 1 to 3 carbon atoms, and more preferably a single bond.

R^{c} represents preferably an alkanediyl group having 1 to 3 carbon atoms, and more preferably a methanediyl group.

R^{d} represents preferably an alkanediyl group having 1 to 3 carbon atoms.

Examples of the substituted or unsubstituted hydrocarbon group having 1 to 20 carbon atoms include:

alkyl groups such as a methyl group, an ethyl group, a propyl group and a butyl group;

fluorinated alkyl groups such as a fluoromethyl group, a trifluoromethyl group, a perfluoroethyl group and a perfluoropropyl group;

saturated alicyclic hydrocarbon groups such as a cyclopentyl group and a cyclohexyl group;

aryl groups such as a phenyl group, a tolyl group, a xylyl group and a naphthyl group;

aralkyl groups such as a benzyl group, a phenethyl group and a naphthylmethyl group;

hydrocarbon groups having a vinyl group exemplified in connection with a monovalent organic group having an ethylenic unsaturated double bond which will be described later; and the like.

In the structural unit U_{g} in the above formula (1), k is 0 or 1. When k is 0, the structural unit U_{g} has three Si—O— bonds. Meanwhile, when k is 1, the structural unit U_{g} has two Si—O— bonds.

When k is 0, due to a greater proportion of Si included in the siloxane polymer component, the oxygen gas etching resistance of the silicon-containing film can be improved. On the other hand, in order to improve the solubility of the siloxane polymer in the organic solvent, k is preferably 1. The structural unit U_{g} wherein k is 0, and the structural unit U_{g} wherein k is 1 may be both included in a single molecule, or each molecule may include the structural unit U_{g} being distinct.

The proportion of the structural unit U_{g} wherein k is 0 and the structural unit U_{g} wherein k is 1 to be included may be predetermined by e.g., a ratio of silane monomers charged in producing the siloxane polymer.

In the structural unit U_{g} in the above formula (1), k is preferably 0.

The silane monomer (I) that gives the structural unit U_{g} has a hydrolyzable group. Examples of the hydrolyzable group include alkoxy groups such as a methoxy group and an ethoxy group; acyloxy groups such as an acetoxy group; halogen atoms such as a fluorine atom; and the like. The silane monomer (I) has preferably two or three hydrolyzable groups, and more preferably three hydrolyzable groups.

Specific examples of the silane monomer (I) include compounds represented by the following formulae (i-1) to (i-6), respectively, and the like.

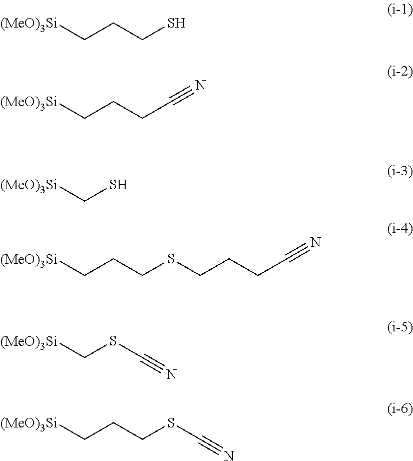

In the polymer component (A), the lower limit of the proportion of the structural unit U_{g} included is preferably 3 mol %, more preferably 5 mol %, still more preferably 10 mol %, and particularly preferably 15 mol %. Including a larger amount of the structural unit U_{g} may lead to further improvements of the etching easiness by CF₄ gas and/or the removability with an acidic liquid of the silicon-containing film obtained. The upper limit of the proportion of the structural unit U_{g} included is preferably 90 mol %, more preferably 70 mol %, still more preferably 50 mol %, and particularly preferably 30 mol %. The proportion of the structural unit included in the polymer component (A) can be assumed to be identical to the proportion of a corresponding silane monomer included in synthesizing the polymer component (A). It is to be noted that the same applies in the following.

Structural Unit Uₕ

In the structural unit Uₕ in the above formula (1), R³ represents a monovalent organic group including an ethylenic unsaturated double bond; and

R⁴ represents a monovalent organic group having an ethylenic unsaturated double bond, or a hydrogen atom, a hydroxy group, a substituted or unsubstituted hydrocarbon group having 1 to 20 carbon atoms.

Examples of the monovalent organic group having an ethylenic unsaturated double bond include: hydrocarbon groups having a vinyl group such as a vinyl group, a vinylmethyl group, a vinylethyl group, a 4-vinylphenyl group, a 3-vinylphenyl group, (4-vinylphenyl)methyl group, a 2-(4-vinylphenyl)ethyl group, (3-vinylphenyl)methyl group, a 2-(3-vinylphenyl)ethyl group, a 4-isopropenylphenyl group, a 3-isopropenylphenyl group, (4-isopropenylphenyl)methyl group, a 2-(4-isopropenylphenyl)ethyl group, (3-isopropenylphenyl)methyl group and a 2-(3-isopropenylphenyl)ethyl group; (meth)acryloyloxyalkyl groups such as a methacryloyloxymethyl group, a methacryloyloxyethyl group, a methacryloyloxypropyl group, a methacryloyloxybutyl group, an acryloyloxymethyl group, an acryloyloxyethyl group, an acryloyloxypropyl group and an acryloyloxybutyl group; and the like.

Examples of the substituted or unsubstituted hydrocarbon group having 1 to 20 carbon atoms include: alkyl groups such as a methyl group, an ethyl group, a propyl group and a butyl group; fluorinated alkyl groups such as a fluoromethyl group, a trifluoromethyl group, a perfluoroethyl group and a perfluoropropyl group; saturated alicyclic hydrocarbon groups such as a cyclopentyl group and a cyclohexyl group; aryl groups such as a phenyl group, a tolyl group, a xylyl group and a naphthyl group; aralkyl groups such as a benzyl group, a phenethyl group and a naphthylmethyl group; hydrocarbon groups having a vinyl group exemplified in connection with the monovalent organic group having an ethylenic unsaturated double bond described above; and the like.

In the structural unit Uₕ in the above formula (1), 1 is 0 or 1. When 1 is 0, the structural unit Uₕ has three Si—O— bonds. Meanwhile, when I is 1, the structural unit Uₕ has two Si—O— bonds.

When 1 is 0, due to a greater proportion of Si included in the polymer component (A), the oxygen gas etching resistance of the silicon-containing film can be improved. On the other hand, in order to improve the solubility of the siloxane polymer in the organic solvent, 1 is preferably 1. The structural unit Uₕ wherein 1 is 0, and the structural unit Uₕ wherein 1 is 1 may be both included in a single molecule, or each molecule may include the structural unit Uₕ being distinct.

The proportion of the structural unit Uₕ wherein 1 is 0, and the structural unit Uₕ wherein 1 is 1 to be included may be predetermined by e.g., a ratio of the monomers charged in producing the siloxane polymer.

In the structural unit Uₕ in the above formula (1), 1 is preferably 0.

Examples of the silane monomer that gives the structural unit Uₕ include (meth)acryloyloxyalkyltrialkylsilanes such as (meth)acryloyloxymethyltrimethoxysilane and (meth)acryloyloxypropyltrimethoxysilane, as well as vinyltrimethoxysilane, vinyltriethoxysilane, 3-vinylphenyltrimethoxysilane, and the like.

When the polymer component (A) includes the structural unit Uₕ, the lower limit of the proportion of the structural unit Uₕ included in the polymer component (A) is preferably 10 mol %, more preferably 20 mol %, still more preferably 40 mol %, and particularly preferably 60 mol %. Including a larger amount of the structural unit Uₕ may lead to a further improvement of the removability with an acidic liquid. The upper limit of the proportion of the structural unit Uₕ included is preferably 95 mol %, more preferably 90 mol %, and particularly preferably 80 mol %.

Structural Unit Uᵢ

In the structural unit Uᵢ in the above formula (1), R⁵ represents a non-crosslinkable monovalent organic group having a photoabsorptive group.

Examples of the non-crosslinkable monovalent organic group having a photoabsorptive group include aryl groups such as a phenyl group, a tolyl group, a xylyl group, a naphthyl group and an anthracenyl group, aralkyl groups such as a benzyl group, a phenethyl group and a naphthylmethyl group, and the like. These groups may have a substituent such as an alkoxy group.

In the structural unit Uᵢ in the above formula (1), R⁶ represents a hydrogen atom, a hydroxy group, a substituted or unsubstituted non-crosslinkable monovalent hydrocarbon group having 1 to 20 carbon atoms.

In the case in which R⁶ represents the substituted or unsubstituted non-crosslinkable hydrocarbon group having 1 to 20 carbon atoms, examples of the non-crosslinkable hydrocarbon group having 1 to 20 carbon atoms include the hydrocarbon groups exemplified in connection with R² described above.

In the structural unit Uᵢ in the above formula (1), m is 0 or 1. When m is 0, the structural unit Uᵢ has three Si—O— bonds. Meanwhile, when m is 1, the structural unit Uᵢ has two Si—O— bonds.

When m is 0, due to a greater proportion of Si included in the polymer component (A), the oxygen gas etching resistance of the siloxane polymer can be improved. On the other hand, in order to improve the solubility of the siloxane polymer in the organic solvent, m is preferably 1. The structural unit Uᵢ wherein m is 0, and the structural unit Uᵢ wherein m is 1 may be both included in a single molecule, or each molecule may include the structural unit Uᵢ being distinct.

The proportion of the structural unit Uᵢ wherein m is 0, and the structural unit Uᵢ wherein m is 1 to be included may be predetermined by, e.g., a ratio of the monomers charged in producing the siloxane polymer.

In the structural unit Uᵢ in the above formula (1), m is preferably 0.

Examples of the silane monomer that gives the silane monomer that gives the structural unit Uᵢ include phenyltrimethoxysilane, phenyltriethoxysilane, methylphenyltrimethoxysilane, and the like.

When the polymer component (A) includes the structural unit Uᵢ, the lower limit of the proportion of the structural unit Uᵢ included in the polymer component (A) is preferably 2 mol %, more preferably 3 mol %, and still more preferably 5 mol %. Including the structural unit Uᵢ enables the substrate reflectance to be further reduced. The upper limit of the proportion of the structural unit Uᵢ is preferably 50 mol %, more preferably 30 mol %, still more preferably 25 mol %, and particularly preferably 15 mol %.

Structural Unit Uⱼ

In the structural unit Uⱼ in the above formula (1), R⁷ represents a substituted or unsubstituted non-crosslinkable and non-photoabsorptive monovalent aliphatic hydrocarbon group, or a substituted or unsubstituted non-crosslinkable and non-photoabsorptive monovalent alicyclic hydrocarbon group.

Examples of the substituted or unsubstituted non-crosslinkable and non-photoabsorptive monovalent aliphatic hydrocarbon group include: alkyl groups such as a methyl group, an ethyl group, a propyl group and a butyl group; fluorinated alkyl groups such as a fluoromethyl group, a trifluoromethyl group, a perfluoroethyl group and a perfluoropropyl group; and the like.

Examples of the substituted or unsubstituted non-crosslinkable and non-photoabsorptive monovalent alicyclic hydrocarbon group include saturated alicyclic hydrocarbon groups such as a cyclopentyl group and a cyclohexyl group, and the like.

In the structural unit Uⱼ in the above formula (1), n is 0 to 2. When n is 0, the structural unit Uⱼ has four Si—O— bonds. Meanwhile, when n is 1, the structural unit Uⱼ has three Si—O— bonds. Whereas, when n is 2, the structural unit Uⱼ has two Si—O— bonds.

When n is 0, due to a greater proportion of Si included in the polymer component (A), the oxygen gas etching resistance of the silicon-containing film can be improved. On the other hand, in order to improve the solubility of the siloxane polymer in the organic solvent, n is preferably 1 or 2. The structural unit Uⱼ wherein n is 0, the structural unit Uⱼ wherein n is 1, and the structural unit Uⱼ wherein n is 2 may be all included in a single molecule, or each molecule may include the structural unit Uⱼ being distinct.

The proportion of the structural unit Uⱼ wherein n is 0, the structural unit U; wherein n is 1, and the structural unit Uⱼ wherein n is 2 to be included may be predetermined by, e.g., a ratio of the monomers charged in producing the siloxane polymer.

In the structural unit U in the above formula (1), n is preferably 0 or 1, and more preferably 0ⱼ.

Examples of the silane monomer that gives the structural unit Uⱼ include tramethoxysilane, tetraethoxysilane, tetrabutoxysilane, methyltrimethoxysilane, methyltriethoxysilane, ethyltrimethoxysilane, dimethyldimethoxysilane, and the like.

When the polymer component (A) includes the structural unit Uⱼ, the lower limit of the proportion of the structural unit Uⱼ included in the polymer component (A) preferably 1 mol %, more preferably 5 mol %, and still more preferably 10 mol %. Including the structural unit Uⱼ enables the oxygen gas etching resistance to be further improved. When improving the oxygen gas etching resistance and the like is intended, the lower limit may be preferably 30 mol %, more preferably 50 mol %, and still more preferably 70 mol %. The upper limit of the proportion of the structural unit Uⱼ is preferably 60 mol %, more preferably 45 mol %, and particularly preferably 30 mol %. When the upper limit of the proportion of the structural unit Uⱼ is less than the upper limit, removability with an acidic liquid can be more favorable. When improving the oxygen gas etching resistance and the like is intended, the upper limit of the proportion of the structural unit Uⱼ may be 90 mol %, or may be 85 mol %.

Other Structural Unit

The polymer component (A) may include as other structural unit, additional structural unit(s) other than the structural unit represented by the above formula (1), within a range not leading to impairment of the effects of the present invention. The lower limit of the total proportion of the structural unit U_{g}, the structural unit Uₕ, the structural unit Uᵢ and the structural unit Uⱼ included in the polymer component (A) is preferably 50 mol %, more preferably 70 mol %, still more preferably 90 mol %, and even more preferably 95 mol %. Meanwhile, the total proportion may be 100 mol %. The other structural unit is exemplified by structural units derived from a hydrolyzable boron compound, a hydrolyzable aluminum compound, a hydrolyzable titanium compound or the like.

Examples of the hydrolyzable boron compound include boron methoxide, boron ethoxide, boron propoxide, boron butoxide, boron amyloxide, boron hexyloxide, boron cyclopentoxide, boron cyclohexyloxide, boron allyloxide, boron phenoxide, boron methoxyethoxide, and the like.

Examples of the hydrolyzable aluminum compound include aluminum methoxide, aluminum ethoxide, aluminum propoxide, aluminum butoxide, aluminum amyloxide, aluminum hexyloxide, aluminum cyclopentoxide, aluminum cyclohexyloxide, aluminum allyloxide, aluminum phenoxide, aluminum methoxyethoxide, aluminum ethoxyethoxide, aluminum dipropoxy(ethyl acetoacetate), aluminum dibutoxy(ethyl acetoacetate), aluminum propoxybis(ethyl acetoacetate), aluminum butoxybis(ethyl acetoacetate), aluminum 2,4-pentanedionate, aluminum 2,2,6,6-tetramethyl-3,5-heptanedionate, and the like.

Examples of the hydrolyzable titanium compound include titanium methoxide, titanium ethoxide, titanium propoxide, titanium butoxide, titanium amyloxide, titanium hexyloxide, titanium cyclopentoxide, titanium cyclohexyloxide, titanium allyloxide, titanium phenoxide, titanium methoxyethoxide, titanium ethoxyethoxide, titanium dipropoxybisethylacetoacetate, titanium dibutoxybisethylacetoacetate, titanium dipropoxybis(2,4-pentanedionate), titanium dibutoxybis(2,4-pentanedionate), oligomers as partial hydrolytic condensation products of these, and the like.

The lower limit of the content of the polymer component (A) with respect to the total solid content of the film-forming material is preferably 50% by mass, more preferably 70% by mass, still more preferably 80% by mass, and particularly preferably 90% by mass. The upper limit of the content is preferably 99% by mass, and more preferably 97% by mass. The total solid content of the film-forming material as referred to herein means the sum of components other than the organic solvent (B) and water (E). The polymer component (A) may be contained either alone of one type, or in combination of two or more types thereof.

The lower limit of the polystyrene equivalent weight average molecular weight (Mw) of the polymer component (A) as determined by size exclusion chromatography is preferably 1,000, more preferably 1,300, and still more preferably 1,500. The upper limit of the Mw is preferably 100,000, more preferably 30,000, still more preferably 10,000, and particularly preferably 4,000.

The Mw of the polymer (A) herein is a value determined by gel permeation chromatography (GPC) using, for example, GPC columns available from Tosoh Corporation (“G2000HXL”×2, “G3000HXL”×1 and “G4000HXL”×1) with mono-dispersed polystyrene as a standard, under analytical conditions involving: a flow rate of 1.0 mL/min; an elution solvent of tetrahydrofuran; and a column temperature of 40° C.

In each embodiment, the polymer component (A) may be produced by a well-known method.

Although not necessarily clarified and without wishing to be bound by any theory, the reason for improvements in CF₄ gas etching easiness, oxygen gas etching resistance and the like owing to the film-forming material containing the polymer component (A) is presumed as follows. Due to the polymer component (A) including at least two selected from the group consisting of a sulfur atom, a nitrogen atom, a boron atom and a phosphorus atom, the boiling point of a gas generated during etching is elevated, and the elevation of the boiling point would affect the etching rate. The polymer component (A) may be a siloxane polymer component including at least two selected from the group consisting of a sulfur atom, a nitrogen atom, a boron atom and a phosphorus atom, other than a combination of a sulfur atom and a nitrogen atom. The structural unit including a boron atom may be introduced by, for example, using as a monomer, boron methoxide, boron ethoxide, boron propoxide, boron butoxide, boron amyloxide, boron hexyloxide, boron cyclopentoxide, boron cyclohexyloxide, boron allyloxide, boron phenoxide, boron methoxyethoxide, boric acid, boron oxide, or the like. The structural unit including a phosphorus atom may be introduced by, for example, using as a monomer, trimethyl phosphite, triethyl phosphite, tripropyl phosphite, trimethyl phosphate, triethyl phosphate, tripropyl phosphate, diphosphorus pentaoxide, or the like.

### (B) Organic Solvent

As the organic solvent (B), any one may be used as long as it is capable of dissolving or dispersing the polymer component (A) and the optional component.

The organic solvent (B) is exemplified by a hydrocarbon solvent, an alcohol solvent, a ketone solvent, an ether solvent, an ester solvent, a nitrogen-containing solvent, a sulfur-containing solvent, and the like.

Examples of the alcohol solvent include monohydric alcohol solvents such as methanol, ethanol, n-propanol, iso-propanol, n-butanol and iso-butanol, polyhydric alcohol solvents such as ethylene glycol, 1,2-propylene glycol, diethylene glycol and dipropylene glycol, and the like.

Examples of the ketone solvent include acetone, methyl ethyl ketone, methyl-n-propyl ketone, methyl-iso-butyl ketone, cyclohexanone, and the like.

Examples of the ether solvent include ethyl ether, iso-propyl ether, ethylene glycol dibutyl ether, diethylene glycol monomethyl ether, diethylene glycol monoethyl ether, diethylene glycol diethyl ether, propylene glycol monomethyl ether, propylene glycol monoethyl ether, propylene glycol monopropyl ether, tetrahydrofuran, and the like.

Examples of the ester solvent include ethyl acetate, γ-butyrolactone, n-butyl acetate, ethylene glycol monomethyl ether acetate, ethylene glycol monoethyl ether acetate, diethylene glycol monomethyl ether acetate, diethylene glycol monoethyl ether acetate, propylene glycol monomethyl ether acetate, propylene glycol monoethyl ether acetate, dipropylene glycol monomethyl ether acetate, dipropylene glycol monoethyl ether acetate, ethyl propionate, n-butyl propionate, methyl lactate, ethyl lactate, and the like.

Examples of the nitrogen-containing solvent include N,N-dimethylformamide, N,N-dimethylacetamide, N-methylpyrrolidone, and the like.

Of these, the ether solvent and the ester solvent are preferred, and the ether solvent and the ester solvent having a glycol structure are more preferred due to superior film formability.

Examples of the ether solvent and the ester solvent having a glycol structure include propylene glycol monomethyl ether, propylene glycol monoethyl ether, propylene glycol monopropyl ether, propylene glycol monomethyl ether acetate, propylene glycol monoethyl ether acetate, propylene glycol monopropyl ether acetate, and the like. Of these, in particular, propylene glycol monomethyl ether acetate is preferred.

The organic solvent (B) may be used either of one type alone, or at least two types thereof may be used in combination.

The lower limit of the content of the organic solvent (B) in the film-forming material of the one embodiment is preferably 80% by mass, more preferably 90% by mass, and still more preferably 95% by mass. The upper limit of the content is preferably 99% by mass, and more preferably 98% by mass.

### (C) Additive

The film-forming material for a resist process according to the present embodiment may contain (C) an additive such as a basic compound, a radical generating agent and an acid generating agent.

Basic Compound

The basic compound (including a base generating agent) is exemplified by a compound having a basic amino group, and a compound that is converted into a compound having a basic amino group by an action of an acid or an action of heat (base generator). More specifically, an amine compound, and as the base generator, an amide group-containing compound, an urea compound, a nitrogen-containing heterocyclic compound, and the like are exemplified. When the film-forming material for a resist process contains the base compound, hardening of the film-forming material can be accelerated, and/or the removability with an acidic liquid of the resulting silicon-containing film and the like can be more improved.

Examples of the amine compound include mono(cyclo)alkylamines, di(cyclo)alkylamines, tri(cyclo)alkylamines, substituted alkylaniline and derivatives thereof, ethylenediamine, N,N,N′,N′-tetramethylethylenediamine, tetramethylenediamine, hexamethylenediamine, 4,4′-diaminodiphenylmethane, 4,4′-diaminodiphenyl ether, 4,4′-diaminobenzophenone, 4,4′-diaminodiphenylamine, 2,2-bis(4-aminophenyl)propane, 2-(3-aminophenyl)-2-(4-aminophenyl)propane, 2-(4-aminophenyl)-2-(3-hydroxyphenyl)propane, 2-(4-aminophenyl)-2-(4-hydroxyphenyl)propane, 1,4-bis(1-(4-aminophenyl)-1-methylethyl)benzene, 1,3-bis(1-(4-aminophenyl)-1-methylethyl)benzene, bis(2-dimethylaminoethyl) ether, bis(2-diethylaminoethyl) ether, 1-(2-hydroxyethyl)-2-imidazolidinone, 2-quinoxalinol, N,N,N′,N′-tetrakis(2-hydroxypropyl)ethylenediamine, N,N,N′,N″N″-pentamethyldiethylenetriamine, and the like.

Examples of the amide group-containing compound include N-t-butoxycarbonyl group-containing amino compounds such as N-t-butoxycarbonyl-4-hydroxypiperidine, N-t-butoxycarbonyl-2-carboxy-4-hydroxypyrrolidine and N-t-butoxycarbonyl-2-carboxypyrrolidine, N-t-amyloxycarbonyl group-containing amino compounds such as N-t-amyloxycarbonyl-4-hydroxypiperidine, N-(9-anthrylmethyloxycarbonyl) group-containing amino compounds such as N-(9-anthrylmethyloxycarbonyl)piperidine, formamide, N-methylformamide, N,N-dimethylformamide, acetamide, N-methylacetamide, N,N-dimethylacetamide, propionamide, benzamide, pyrrolidone, N-methylpyrrolidone, N-acetyl-1-adamantylamine, and the like.

Examples of the urea compound include urea, methylurea, 1,1-dimethylurea, 1,3-dimethylurea, 1,1,3,3-tetramethylurea, 1,3-diphenylurea, tri-n-butylthiourea, and the like.

Examples of the nitrogen-containing heterocyclic compound include imidazoles, pyridines, piperazines, pyrazine, pyrazole, pyridazine, quinoxaline, purine, pyrrolidine, piperidine, piperidine ethanol, 3-(N-piperidino)-1,2-propanediol, morpholine, 4-methylmorpholine, 1-(4-morpholinyl)ethanol, 4-acetylmorpholine, 3-(N-morpholino)-1,2-propanediol, 1,4-dimethylpiperazine, 1,4-diazabicyclo[2.2.2]octane, and the like.

In the present embodiment, the amide group-containing compounds and the nitrogen-containing heterocyclic compounds, of these, are particularly preferred. The amide group-containing compound is more preferably a N-t-butoxycarbonyl group-containing amino compound, a N-t-amyloxycarbonyl group-containing amino compound and a N-(9-anthrylmethyloxycarbonyl) group-containing amino compound, and still more preferably N-t-butoxycarbonyl-4-hydroxypiperidine, N-t-butoxycarbonyl-2-carboxy-4-hydroxypyrrolidine, N-t-butoxycarbonyl-2-carboxy-pyrrolidine, N-t-amyloxycarbonyl-4-hydroxypiperidine, and N-(9-anthrylmethyloxycarbonyl)piperidine. The nitrogen-containing heterocyclic compound is preferably 3-(N-piperidino)-1,2-propanediol.

When the film-forming material contains the basic compound, the content of the basic compound with respect to 100 parts by mass of the polymer component (A) is preferably 0.01 parts by mass, more preferably 0.1 parts by mass, still more preferably 0.5 parts by mass, and particularly preferably 1 part by mass. The upper limit of the content is preferably 20 parts by mass, more preferably 10 parts by mass, and still more preferably 5 parts by mass.

The lower limit of the content of the basic compound in the film-forming material is preferably 0.01% by mass, more preferably 0.03% by mass, and still more preferably 0.05% by mass. On the other hand, the upper limit of the content is preferably 5% by mass, more preferably 1% by mass, and still more preferably 0.3% by mass.

Radical Generating Agent

The radical generating agent is a compound that generates a radical by a radioactive ray such as an ultraviolet ray, and/or heating. As the radical generating agent, an organic peroxide, a diazo compound, an alkylphenone compound, a carbazole oxime compound, an O-acyloxime compound, a benzophenone compound, a thiaxanthone compound, a biimidazole compound, a triazine compound, an onium salt compound, a benzoin compound, α-diketone compound, a polynuclear quinone compound, an imidesulfonate compound, or the like may be used. When the film-forming material for a resist process contains the radical generating agent, hardening of the film-forming material may be promoted, and thus the strength of the resulting hardened film can be enhanced.

Specific examples of the organic peroxide include:

diacyl peroxides such as dibenzoyl peroxide, diisobutyroyl peroxide, bis(2,4-dichlorobenzoyl) peroxide, (3,5,5-trimethylhexanoyl) peroxide, dioctanoyl peroxide, dilauroyl peroxide and distearoyl peroxide,

hydroperoxides such as hydrogen peroxide, t-butyl hydroperoxide, cumene hydroperoxide, p-menthane hydroperoxide, diisopropylbenzene hydroperoxide, 1,1,3,3-tetramethylbutyl hydroperoxide and t-hexyl hydroperoxide,

dialkyl peroxides such as di-t-butyl peroxide, dicumyl peroxide, dilauryl peroxide, peroxide, α,α′-bis(t-butylperoxy)diisopropylbenzene, 2,5-dimethyl-2,5-bis(t-butylperoxy)hexane, t-butylcumyl peroxide and 2,5-dimethyl-2,5-bis(t-butylperoxy)hexyne, peroxy esters such as t-butylperoxy acetate, t-butylperoxy pivalate, t-hexylperoxy pivalate, 1,1,3,3-tetramethylbutylperoxy 2-ethylhexanoate, 2,5-dimethyl-2,5-bis(2-ethylhexanoylperoxy)hexane, 1-cyclohexyl-1-methylethylperoxy 2-ethylhexanoate, t-hexylperoxy 2-ethylhexanoate, t-butylperoxy 2-ethylhexanoate, t-butylperoxy isobutyrate, t-butylperoxy maleate, t-butylperoxy 3,5,5-trimethylhexanoate, t-butylperoxy laurate, 2,5-dimethyl-2,5-bis(m-toluoylperoxy)hexane, α,α′-bis(neodecanoylperoxy)diisopropylbenzene, cumylperoxy neodecanoate, 1,1,3,3,-tetramethylbutylperoxy neodecanoate, 1-cyclohexyl-1-methylethylperoxy neodecanoate, t-hexylperoxy neodecanoate, t-hexylperoxy neododecanoate, t-butylperoxy benzoate, t-hexylperoxy benzoate, bis(t-butylperoxy) isophthalate, 2,5-dimethyl-2,5-bis(benzoylperoxy)hexane, t-butylperoxy m-toluoylbenzoate and 3,3′,4,4′-tetra(t-butylperoxycarbonyl)benzophenone,

peroxyketals such as 1,1-bis(t-hexylperoxy)3,3,5-trimethylcyclohexane, 1,1-bis(t-hexylperoxy)cyclohexane, 1,1-bis(t-butylperoxy)3,3,5-trimethylcyclohexane, 1,1-bis(t-butylperoxy)cyclohexane, 1,1-bis(t-butylperoxy)cyclododecane, 2,2-bis(t-butylperoxy)butane, n-butyl-4,4-bis(t-butylperoxy) valerate and 2,2-bis(4,4-di-t-butylperoxycyclohexyl)propane,

peroxy carbonates such as t-hexylperoxy isopropyl carbonate, t-butylperoxy isopropyl carbonate, t-butylperoxy-2-ethylhexyl carbonate, t-butylperoxy allyl carbonate, di-n-propylperoxy carbonate, diisopropylperoxy carbonate, bis(4-t-butylcyclohexyl)peroxy carbonate, di-2-ethoxyethylperoxy carbonate, di-2-ethylhexylperoxy carbonate, di-2-methoxybutylperoxy carbonate and di(3-methyl-3-methoxybutyl)peroxy carbonate; and the like.

Specific examples of the diazo compound include azoisobutyronitrile, azobisisovaleronitrile, 2,2-azobis(4-methoxy-2,4-dimethylvaleronitrile), 2,2-azobis(2,4-dimethylvaleronitrile), 2,2-azobis(2-methylbutyronitrile), 1,1′-azobis(cyclohexane-1-carbonitrile), 2-(carbamoylazo)isobutyronitrile, 2,2-azobis[2-methyl-N-[1,1-bis(hydroxylmethyl)-2-hydroxylethyl]propionamide], 2,2-azobis(2-methyl-N-(2-hydroxylethyl)propionamide), 2,2-azobis[N-(2-propenyl)2-methylpropionamide], 2,2-azobis(N-butyl-2-methylpropionamide), 2,2-azobis(N-cyclohexyl-2-methylpropionamide), 2,2-azobis[2-(5-methyl-2-imidazolin-2-yl)propane]dihydrochloride, 2,2-azobis[2-(2-imidazolin-2-yl)propane]dihydrochloride, 2,2-azobis[2-(2-imidazolin-2-yl)propane]disulfate.dihydrate, 2,2-azobis[2-(3,4,5,6-tetrahydropyrimidin-2-yl)propane]dihydrochloride, 2,2-azobis[2-[1-(2-hydroxyethyl)2-imidazolin-2-yl]propane]dihydrochloride, 2,2-azobis(2-(2-imidazolin-2-yl)propane), 2,2-azobis(2-methylpropioneamidine)dihydrochloride, 2,2-azobis[N-(2-carboxyethyl)2-methylpropioneamidine], 2,2-azobis(2-methylpropionamidoxime), dimethyl 2,2′-azobisbutyrate, 4,4′-azobis(4-cyanopentanoic acid), 2,2-azobis(2,4,4-trimethylpentane), and the like.

Examples of the alkylphenone compound include 1-hydroxy-cyclohexyl-phenyl-ketone, 2,2-dimethoxy-1,2-diphenylethan-1-one, 2-hydroxy-2-methyl-1-phenyl-propan-1-one, 1-[4-(2-hydroxyethoxy)-phenyl]-2-hydroxy-2-methyl-1-propan-1-one, 2-hydroxy-1-{4-[4-(2-hydroxy-2-methyl-propionyl)-benzyl]phenyl}-2-methyl-propan-1-one, 2-methyl-1-(4-methylthiophenyl)-2-morpholinopropan-1-one, 2-benzyl-2-dimethylamino-1-(4-morpholinophenyl)-butanone-1, and the like.

These radical generating agent may be each used either alone of one type, or in combination of two or more types thereof.

When the film-forming material contains the radical generating agent, the content of the radical generating agent with respect to 100 parts by mass of the polymer component (A) is preferably 0.01 parts by mass, more preferably 0.1 parts by mass, still more preferably 0.5 parts by mass, and particularly preferably 1 part by mass. The upper limit of the content is preferably 20 parts by mass, more preferably 10 parts by mass, and still more preferably 5 parts by mass.

Also, the lower limit of the content of the radical generating agent in the film-forming material is preferably 0.01% by mass, more preferably 0.03% by mass, and still more preferably 0.05% by mass. On the other hand, the upper limit of the content is preferably 5% by mass, more preferably 1% by mass, and still more preferably 0.3% by mass.

Acid Generating Agent

The acid generating agent is a compound that generates an acid upon irradiation with a radioactive ray such as a ultraviolet ray, and/or heating. When the material for forming a silicon-containing film contains the acid generating agent, hardening can be promoted, and consequently the strength of the silicon-containing film can be more enhanced, and the solvent resistance and the oxygen gas etching resistance can be improved. The acid generating agent may be used either alone of one type, or in combination of two or more types thereof.

The acid generating agent is exemplified by an onium salt compound, an N-sulfonyloxyimide compound, and the like.

Exemplary onium salt compound includes a sulfonium salt, a tetrahydrothiophenium salt, an iodonium salt, an ammonium salt, and the like.

Examples of the sulfonium salt include sulfonium salts described in paragraph [0110] of Japanese Unexamined Patent Application, Publication No. 2014-037386, and specific examples include triphenylsulfonium trifluoromethanesulfonate, triphenylsulfonium nonafluoro-n-butanesulfonate, triphenylsulfonium 2-bicyclo[2.2.1]hept-2-yl-1,1,2,2-tetrafluoroethanesulfonate, 4-cyclohexylphenyldiphenylsulfonium trifluoromethanesulfonate, and the like.

Examples of the tetrahydrothiophenium salt include tetrahydrothiophenium salts described in paragraph [0111] of Japanese Unexamined Patent Application, Publication No. 2014-037386, and specific examples thereof include 1-(4-n-butoxynaphthalen-1-yl)tetrahydrothiophenium trifluoromethanesulfonate, 1-(4-n-butoxynaphthalen-1-yl)tetrahydrothiophenium nonafluoro-n-butanesulfonate, 1-(4-n-butoxynaphthalen-1-yl)tetrahydrothiophenium 2-bicyclo[2.2.1]hept-2-yl-1,1,2,2-tetrafluoroethanesulfonate, and the like.

Examples of the iodonium salt include iodonium salts described in paragraph [0112] of Japanese Unexamined Patent Application, Publication No. 2014-037386, and specific examples thereof include diphenyliodonium trifluoromethanesulfonate, diphenyliodonium nonafluoro-n-butanesulfonate, diphenyliodonium 2-bicyclo[2.2.1]hept-2-yl-1,1,2,2-tetrafluoroethanesulfonate, bis(4-t-butylphenyl)iodonium nonafluoro-n-butanesulfonate, and the like.

Examples of the ammonium salt include trimethylammonium nonafluoro-n-butanesulfonate, triethylammonium nonafluoro-n-butanesulfonate, and the like.

Examples of the N-sulfonyloxyimide compound include N-sulfonyloxyimide compounds described in paragraph [0113] of Japanese Unexamined Patent Application, Publication No. 2014-037386, and specific examples include N-(trifluoromethanesulfonyloxy)bicyclo[2.2.1]hept-5-ene-2,3-dicarboxyimide, N-(nonafluoro-n-butanesulfonyloxy)bicyclo[2.2.1]hept-5-ene-2,3-dicarboxyimide, N-(2-bicyclo[2.2.1]hept-2-yl-1,1,2,2-tetrafluoroethanesulfonyloxy)bicyclo[2.2.1]hept-5-ene-2,3-dicarboxyimide, and the like.

When the film-forming material contains the acid generating agent, the content of the acid generating agent with respect to 100 parts by mass of the polymer component (A) is preferably 0.01 parts by mass, more preferably 0.1 parts by mass, still more preferably 0.5 parts by mass, and particularly preferably 1 part by mass. The upper limit of the content is preferably 20 parts by mass, more preferably 10 parts by mass, and still more preferably 5 parts by mass.

Furthermore, the lower limit of the content of the acid generating agent in the film-forming material is preferably 0.01% by mass, more preferably 0.03% by mass, and still more preferably 0.05% by mass. On the other hand, the upper limit of the content is preferably 5% by mass, more preferably 1% by mass, and still more preferably 0.3% by mass.

### (D) Crosslinking Agent

The film-forming material for a resist process according to the present embodiment may also contain (D) a crosslinking agent. The crosslinking agent (D) is exemplified by a compound (d-1) that includes an ethylenic unsaturated double bond, a compound (d-2) that includes a functional group represented by the following formula (i), and the like.

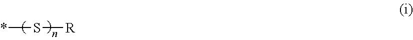

In the formula (i), R represents a hydrogen atom, or a monovalent organic group having 1 to 30 carbon atoms; n is an integer of 1 to 5; and * denotes a bonding site.

Compound (d-1)

As the compound (d-1), a well-known compound may be used through freely selecting one, or two or more types, as long as it includes an ethylenic unsaturated double bond and does not impair the effects of the invention. The compound (d-1) is exemplified by a compound that includes at least one selected from a polyfunctional (meth)acrylate compound, a compounds having at least two alkenyloxy groups, hydrocarbons having at least two alkenyl groups and the like.

The polyfunctional (meth)acrylate is not particularly limited as long as it is a compound having at least two (meth)acryloyl groups, and is exemplified by: a polyfunctional (meth)acrylate obtained by allowing an aliphatic polyhydroxy compound to react with (meth)acrylic acid; a caprolactone-modified polyfunctional (meth)acrylate; an alkylene oxide-modified polyfunctional (meth)acrylate; a polyfunctional urethane (meth)acrylate obtained by allowing (meth)acrylate having a hydroxyl group to react with polyfunctional isocyanate; a polyfunctional (meth)acrylate having a carboxyl group obtained by allowing (meth)acrylate having a hydroxyl group to react with an acid anhydride; and the like.

Specific examples of the polyfunctional (meth)acrylate include trimethylolpropane tri(meth)acrylate, ditrimethylolpropane tetra(meth)acrylate, pentaerythritol tri(meth)acrylate, pentaerythritol tetra(meth)acrylate, dipentaerythritol penta(meth)acrylate, dipentaerythritol hexa(meth)acrylate, glycerin tri(meth)acrylate, tris(2-hydroxyethyl)isocyanurate tri(meth)acrylate, ethylene glycol di(meth)acrylate, 1,3-butanediol di(meth)acrylate, 1,4-butanediol di(meth)acrylate, 1,6-hexanediol di(meth)acrylate, neopentyl glycol di(meth)acrylate, diethylene glycol di(meth)acrylate, triethylene glycol di(meth)acrylate, dipropylene glycol di(meth)acrylate, bis(2-hydroxyethyl)isocyanurate di(meth)acrylate, and the like.

Examples of the compound having at least two alkenyloxy groups include ethylene glycol divinyl ether, diethylene glycol divinyl ether, triethylene glycol divinyl ether, trimethylolpropane diallyl ether, pentaerythritol triallyl ether, polyallyl (meth)acrylate, and the like.

Examples of the hydrocarbon having at least two alkenyl groups include divinylbenzene, and the like.

Compound (d-2)

As the compound (d-2), a well-known compound may be used through freely selecting one, or two or more types, as long as it includes a functional group represented by the above formula (i) and does not impair the effects of the invention. The compound (d-2) is preferably the compound having the functional group represented by the formula (i), wherein n is 1 and R represents a hydrogen atom, or the compound having the functional group represented by the formula (i), wherein n is 2 to 5 and R represents a monovalent organic group having 1 to 30 carbon atoms. Such compounds are exemplified by a polyhydric thiol compound, a thio ester compound, a sulfide compound, a polysulfide compound, and the like.

The polyfunctional thiol compound is a compound having at least two mercapto groups in a single molecule. Specific examples thereof include: compounds having two mercapto groups such as 1,2-ethanedithiol, 1,3-propanedithiol, 1,4-butanedithiol, 2,3-butanedithiol, 1,5-pentanedithiol, 1,6-hexanedithiol, 1,8-octanedithiol, 1,9-nonanedithiol, 2,3-dimercapto-1-propanol, dithioerythritol, 2,3-dimercaptosuccinic acid, 1,2-benzenedithiol, 1,2-benzenedimethanethiol, 1,3-benzenedithiol, 1,3-benzenedimethanethiol, 1,4-benzenedimethanethiol, 3,4-dimercaptotoluene, 4-chloro-1,3-benzenedithiol, 2,4,6-trimethyl-1,3-benzenedimethanethiol, 4,4′-thiodiphenol, 2-hexylamino-4,6-dimercapto-1,3,5-triazine, 2-diethylamino-4,6-dimercapto-1,3,5-triazine, 2-cyclohexylamino-4,6-dimercapto-1,3,5-triazine, 2-di-n-butylamino-4,6-dimercapto-1,3,5-triazine, ethylene glycol bis(3-mercaptopropionate), butanediol bisthioglycolate, ethylene glycol bisthioglycolate, 2,5-dimercapto-1,3,4-thiadiazole, 2,2′-(ethylenedithio)diethanethiol and 2,2-bis(2-hydroxy-3-mercaptopropoxyphenylpropane); compounds having three mercapto groups such as 1,2,6-hexanetriol trithioglycolate, 1,3,5-trithiocyanuric acid, trimethylolpropane tris(3-mercaptopropionate), trimethylolpropane tristhioglycolate and 1,3,5-tris(3-mercaptobutyryloxyethyl)-1,3,5-triazine-2,4,6 (1H, 3H, 5H)-trione; compounds having four mercapto groups such as pentaerythritol tetrakis(2-mercaptoacetate), pentaerythritol tetrakis(2-mercaptopropionate), pentaerythritol tetrakis(3-mercaptopropionate) and pentaerythritol tetrakis(3-mercaptobutyrate).

These polyfunctional thiol compounds may be used alone, or as a mixture of two or more types thereof.

Of these, the compounds having three mercapto groups, and the compounds having at least four mercapto groups are preferred. More specifically, pentaerythritol tetrakis(2-mercaptoacetate), pentaerythritol tetrakis(2-mercaptopropionate), pentaerythritol tetrakis(3-mercaptopropionate), pentaerythritol tetrakis(3-mercaptobutyrate), and 1,3,5-tris(3-mercaptobutyryloxyethyl)-1,3,5-triazine-2,4,6 (1H, 3H, 5H)-trione are preferred.

Exemplary commercially available products of the polyfunctional thiol compound include pentaerythritol tetrakis(3-mercaptopropionate) (manufactured by Wako Pure Chemical Industries, Ltd.), pentaerythritol tetrakis(3-mercaptobutyrate) (“Karenz MT PEI”, available from Showa Denko K.K.), 1,3,5-tris(3-mercaptobutyryloxyethyl)-1,3,5-triazine-2,4,6(1H, 3H, 5H)-trione (“Karenz MT NR1”, available from Showa Denko K.K.), and the like.

Examples of the thio ester compound include pentaerythritol tetrakis(2-((t-butoxycarbonyl)thio)acetate), pentaerythritol tetrakis(2-((t-butoxycarbonyl)thio)propionate), pentaerythritol tetrakis(3-((t-butoxycarbonyl)thio)propionate), pentaerythritol tetrakis(3-(t-butoxycarbonyl)thio)butyrate), and the like.

The sulfide compound is exemplified by dialkyl sulfide, dicycloalkyl sulfide, diaryl sulfide, and the like.

Specific examples of the dialkyl sulfide include dimethyl sulfide, diethyl sulfide, di-n-propylsulfide, diisopropyl sulfide, di-n-butylsulfide, diisobutyl sulfide, di-t-butylsulfide, and the like.

Specific examples of the dicycloalkyl sulfide include dicyclopropyl sulfide, dicyclobutyl sulfide, dicyclopentyl sulfide, dicyclohexyl sulfide, dicyclooctyl sulfide, di-2-methylcyclohexyl sulfide, di-2-t-butylcyclohexyl sulfide, and the like.

Specific examples of the diaryl sulfide include diphenyl sulfide, di-2-pyridyl sulfide, di-o-tolyl sulfide, di-m-tolyl sulfide, di-p-tolyl sulfide, and the like.

Examples of the polysulfide compound include 3,3′-bis(triethoxysilylpropyl)disulfide, 3,3′-bis(trimethoxysilylpropyl)disulfide, 3,3′-bis(tributoxysilyl-propyl)disulfide, 3,3′-bis(tripropoxylpropyl)disulfide, 3,3′-bis(trihexoxysilylpropyl)disulfide, 2,2′-bis(dimethylmethoxysilylethyl)disulfide, 3,3′-bis(diphenylcyclohexoxysilylpropyl)disulfide, 3,3′-bis(ethyl-di-butoxysilylpropyl)disulfide, 3,3′-bis(propyldiethoxysilylpropyl)disulfide, 3,3′-bis(triisopropoxysilylpropyl)disulfide, 3,3′-bis(dimethoxyphenylsilyl-2-methylpropyl)disulfide, bis(3-triethoxysilylpropyl)tetrasulfide, bis(2-triethoxysilylethyl)tetrasulfide, bis(3-trimethoxysilylpropyl)tetrasulfide, 3-trimethoxysilylpropyl-N,N-dimethylthiocarbamoyltetrasulfide, 3-triethoxysilylpropyl-N,N-dimethylthiocarbamoyltetrasulfide, 2-triethoxysilyl-N,N-dimethylthiocarbamoyltetrasulfide, 3-trimethoxysilylpropyl-benzothiazoletetrasulfide, 3-triethoxysilylpropylbenzothiazoletetrasulfide, and the like.

The lower limit of the content of the crosslinking agent (D) with respect to 100 parts by mass of the polymer component (A) is preferably 10 parts by mass, and more preferably 20 parts by mass. The upper limit of the content is preferably 80 parts by mass, more preferably 60 parts by mass, and still more preferably 40 parts by mass. When the content of the crosslinking agent (D) is greater than the upper limit, the oxygen gas etching resistance may be deteriorated.

### (E) Water

The film-forming material may contain (E) water, as needed. When the film-forming material further contains water (E), the polymer component (A) and the like may be hydrated, and thus the storage stability may be improved. In addition, containing water (E) may promote the hardening during the film formation, whereby a compact silicon-containing film may be obtained.

When the film-forming material contains water (E), the lower limit of the content of water (E) is preferably 0.01% by mass, more preferably 0.1% by mass, and still more preferably 0.3% by mass. The upper limit of the content is preferably 10% by mass, more preferably 5% by mass, still more preferably 2% by mass, and particularly preferably 1% by mass. When the content of water is greater than the upper limit, the storage stability may be deteriorated, and evenness of the coating film may be inferior.

### Other Optional Component

The film-forming material may contain other other optional components in addition to the components (A) to (E). The other optional component may be, for example, a surfactant, colloidal silica, colloidal alumina, an organic polymer, and the like. When the film-forming material contains the other optional component(s), the upper limit of the content with respect to 100 parts by mass of the polymer component (A) is preferably 2 parts by mass, and more preferably 1 part by mass.

### Preparation Method of Film-Forming Material for Resist Process

The preparation method of the film-forming material is not particularly limited, and may be prepared by, for example, mixing the polymer component (A), the organic solvent (B) and as needed, the other component(s) at a certain ratio, preferably followed by filtering a mixed solution obtained through a filter having a pore size of 0.2 μm.

The lower limit of the solid content concentration of the film-forming material is preferably 0.01% by mass, more preferably 0.1% by mass, still more preferably 0.5% by mass, and particularly preferably 1% by mass. The upper limit of the solid content concentration is preferably 20% by mass, more preferably 10% by mass, still more preferably 5% by mass, and particularly preferably 3% by mass.

### Use and Silicon-Containing Film

The silicon-containing film obtained from the film-forming material is superior in both etching easiness for CF₄ gas and etching resistance against oxygen gas, or exhibits removability with an acidic liquid, etching easiness for CF₄ gas and etching resistance against oxygen gas, each being favorable in a well-harmonized manner. Therefore, the film-forming material can be suitably used as a resist underlayer film-forming material and a resist interfilm-forming material in resist processes, particularly in multilayer resist processes. Moreover, among the multilayer resist processes, the film-forming material can be particularly suitably used in pattern formation in which a multilayer resist process in a more minute field than 90 nm (ArF, ArF in liquid immersion lithography, F₂, EUV, nanoimprinting, etc.) is employed.

The silicon-containing film may be formed by applying the film-forming material on the surface of a substrate or other underlayer film such as an organic underlayer film to form a coating film, and hardening the coating film by subjecting to a heat treatment.

The application procedure of the film-forming material is exemplified by spin coating, roll coating, dip coating, and the like. The temperature of the heat treatment is typically no less than 50° C. and no greater than 450° C. The average thickness of the silicon-containing film formed is typically no less than 10 nm and no greater than 200 nm.

It is to be noted that the film-forming material may be used for intended use of resist processes other than formation of resist underlayer films in resist processes such as, for example, as a forming material of a pattern obtained through a reversal process (reversal pattern) and the like.

Pattern-Forming Method

The pattern-forming method according to the present embodiment includes at least the steps of: (1) applying the film-forming material of the one embodiment onto a substrate to form a silicon-containing film (hereinafter, may be also referred to as “step (1)”); (2) forming a pattern using the silicon-containing film as a mask (hereinafter, may be also referred to as “step (2)”); and (3) removing the silicon-containing film (hereinafter, may be also referred to as “step (3)”).

In addition, the pattern-forming method may further include, as needed, the steps of: (0) forming a resist underlayer film on the substrate before the step for forming the silicon-containing film (hereinafter, may be also referred to as “step (0)”); (1-2) forming a resist pattern directly or indirectly on the upper side of the silicon-containing film (hereinafter, may be also referred to as “step (1-2)”); and (1-3) etching the silicon-containing film using the resist pattern as a mask (hereinafter, may be also referred to as “step (1-3)”).

Step (0) In the step (0), the resist underlayer film is formed on the substrate. In the present embodiment, the step (0) may be carried out as needed.

In the present embodiment, when the step (0) is to be carried out, the step (0) would be followed by the step (1), and in the step (1), and the silicon-containing film would be formed on the resist underlayer film by using the material for forming a silicon-containing film according to the present embodiment.

As the substrate, conventionally well-known substrates such as a silicon wafer, and a wafer coated with aluminum, and the like may be exemplified. In addition, insulating films of silicon oxide, silicon nitride, silicon nitride oxide, polysiloxane, etc., and the like may be also exemplified.

Also a patterned substrate provided with a wiring gutter (trench), a plug groove (via) or the like may be used as the substrate.

The resist underlayer film may be formed by using, for example, a material that is commercially available under a trade name of “NFC HM8005”, etc., available from JSR Corporation, or the like. The resist underlayer film in the present embodiment is typically formed from an organic material.

The forming method of the resist underlayer film is not particularly limited, and the resist underlayer film can be formed by, for example, applying the material for resist underlayer film formation on the substrate by a well-known procedure such as spin coating to form a coating film, and hardening the coating film by exposing and/or heating.

Examples of the radioactive ray used in the exposure include visible light rays, ultraviolet rays, far ultraviolet rays, X-rays, electron beams, γ-rays, molecular beams, ion beams, and the like.

The temperature in heating the coating film is not particularly limited, and is preferably no less than 90° C. and no greater than 550° C., more preferably no greater than 450° C. and, and still more preferably no greater than 300° C.

The film thickness of the resist underlayer film is not particularly limited, and is preferably no less than 50 nm and no greater than 20,000 nm.

### Step (1)

In the step (1), the film-forming material according to the present embodiment is used to form a silicon-containing film on the substrate, directly or via the other layer such as the resist underlayer film. Accordingly, a silicon-containing film-provided substrate is obtained which is a substrate on which the silicon-containing film is formed.

The forming method of the silicon-containing film is not particularly limited, and the silicon-containing film can be formed by, for example, applying the film-forming material on the substrate by a well-known procedure such as spin coating to form a coating film, and hardening the coating film by exposing and/or heating.

Examples of the radioactive ray used in the exposure include visible light rays, ultraviolet rays, far ultraviolet rays, X-rays, electron beams, γ-rays, molecular beams, ion beams, and the like.

The lower limit of the temperature in heating the coating film is preferably 90° C., more preferably 150° C., and still more preferably 200° C. The upper limit of the temperature is preferably 550° C., more preferably 450° C., and still more preferably 300° C. The lower limit of the average thickness of the silicon-containing film formed is preferably 1 nm, more preferably 10 nm, and still more preferably 20 nm. The upper limit of the average thickness is preferably 20,000 nm, more preferably 1,000 nm, and still more preferably 100 nm.

### Step (1-2)

In the step (1-2), the resist pattern is formed directly or indirectly on the upper side of the silicon-containing film obtained in the step (1). The procedure for forming the resist pattern in this step which may be employed includes conventionally well-known procedures such as e.g., a procedure of using a radiation-sensitive resist composition, a procedure in which nanoimprinting lithography is used. The resist pattern is typically formed from an organic material.

### Step (1-3)

In the step (1-3), the silicon-containing film is patterned by one or a plurality of times of etching using the resist pattern obtained in the step (1-2) as a mask.

The etching may be carried out by using, for example, a well-known dry etching apparatus. The etching gas used in the dry etching may be appropriately selected depending on the composition of elements of the silicon-containing film to be etched. For example, a fluorine gas such as CHF₃, CF₄, C₂F₆, C₃F₈ and SF₆, a chlorine gas such as Cl₂ and BCl₃, an oxygen gas such as O₂, O₃ and H₂O, a reductive gas such as H₂, NH₃, CO, CO₂, CH₄, C₂H₂, C₂H₄, C₂H₆, C₃H₄, C₃H₆, C₃H₈, HF, HI, HBr, HCl, NO, NH₃ and BCl₃, an inert gas such as He, N₂ and Ar may be used, and these gases may be used as a mixture. For the dry etching of the silicon-containing film, the fluorine gas is typically used, and a mixture of the fluorine gas with the oxygen gas and the inert gas is suitably used.

### Step (2)

In the step (2), a pattern is formed using the silicon-containing film as a mask. More specifically, a pattern is formed on the substrate by one or a plurality of times of etching using the pattern formed on the silicon-containing film obtained in the step (1-3) as a mask.

When the resist underlayer film is formed the substrate, the resist underlayer film is dry-etched to form the pattern of the resist underlayer film, and thereafter the pattern formation of the substrate is enabled.

The dry etching in forming the pattern on the resist underlayer film may be carried out by using a well-known dry etching apparatus. The etching gas may be appropriately selected depending on the composition of elements of the resist underlayer film to be etched. For example, a fluorine gas such as CHF₃, CF₄, C₂F₆, C₃F₈ and SF₆, a chlorine gas such as Cl₂ and BCl₃, an oxygen gas such as O₂, O₃ and H₂O, a reductive gas such as H₂, NH₃, CO, CO₂, CH₄, C₂H₂, C₂H₄, C₂H₆, C₃H₄, C₃H₆, C₃H₈, HF, HI, HBr, HCl, NO, NH₃ and BCl₃, an inert gas such as He, N₂ and Ar may be used, and these gases may be used as a mixture. For the dry etching of the resist underlayer film by using the pattern of the silicon-containing film as a mask, the oxygen gas is typically used.

The step of further dry etching the substrate using the pattern of the resist underlayer film as a mask may be carried out by using a well-known dry etching apparatus. The etching gas used in the dry etching may be appropriately selected depending on the composition of elements of the organic underlayer film and the substrate to be etched. For example, a fluorine gas such as CHF₃, CF₄, C₂F₆, C₃F₈ and SF₆, a chlorine gas such as Cl₂ and BCl₃, an oxygen gas such as O₂, O₃ and H₂O, a reductive gas such as H₂, NH₃, CO, CO₂, CH₄, C₂H₂, C₂H₄, C₂H₆, C₃H₄, C₃H₆, C₃H₈, HF, HI, HBr, HCl, NO, NH₃ and BCl₃, an inert gas such as He, N₂ and Ar may be used. The etching may be carried out with different etching gases a plurality of times. It is to be noted that in a case in which the silicon-containing film remains on the upper side of the resist underlayer pattern, the silicon-containing film can be removed in the step of removing the silicon-containing film described later.

### Step (3)

In the step (3), the silicon-containing film remaining on the upper face side of the substrate after carrying out the step (2) is eliminated. The step of the removing of the silicon-containing film may be a step of bringing a basic liquid or an acidic liquid into contact with the silicon-containing film. Accordingly, the silicon-containing film is eliminated, i.e., wet removed. In the present embodiment, the step of bringing an acidic liquid into contact is preferred.

The acidic liquid used in the wet removing is not particularly limited as long as it is acidic, and examples thereof include sulfuric acid, a mix liquid of sulfuric acid with aqueous hydrogen peroxide (SPM), a mix liquid of hydrochloric acid with aqueous hydrogen peroxide (HPM), a mix liquid of hydrofluoric acid with aqueous hydrogen peroxide (FPM), a diluted liquid of hydrofluoric acid in pure water (DHF), and the like.

Also, an appropriate amount of a water soluble organic solvent, a surfactant and the like may be added to the acidic liquid described above. Alternatively, a solution containing an organic solvent other than water may be employed as long as it is an acidic liquid.

The pH of the acidic liquid is preferably no greater than 2, and more preferably no greater than 1.

The wet removing procedure is not particularly limited as long as it is a procedure that enables the acidic liquid to be in contact with the silicon-containing film for a certain time period of time, and the wet removing procedure is exemplified by a procedure of immersing the patterned substrate in the acidic liquid, a procedure of spraying the acidic liquid, a procedure of applying the acidic liquid, and the like. After each of such procedures, the substrate may be washed with water, and then dried.

It is to be noted that setting of the immersion time period in the aforementioned procedure of immersing the patterned substrate may be, for example, about 0.2 min to 30 min. However, since a longer immersion time period may cause a damage to the substrate, the setting of the immersion time period is preferably within 20 min, and more preferably within 5 min.

The preset temperature in the step (3) is not particularly limited, and is preferably 20 to 200° C.

### EXAMPLES

Hereinafter, Examples of the embodiments of the present invention are described. It is to be noted that the following Examples merely illustrate typical Examples of the embodiments of the present invention, and the Examples should not be construed to narrow the scope of the present invention.

Determination of the proportion of the solid content included, and the measurement of the weight average molecular weight (Mw) in Examples herein were performed in accordance with the following methods.

Solid Content Concentration of Siloxane Polymer Solution

A siloxane polymer solution in an amount of 0.5 g was baked at 250° C. for 30 min, and the mass of the solid content with respect to 0.5 g of the siloxane polymer solution was measured to calculate the solid content concentration (% by mass) of the siloxane polymer solution.

Measurement of Weight Average Molecular Weight (Mw)

The Mw was measured by gel permeation chromatography (detector: differential refractometer) using, for example, GPC columns (“G2000HXL”×2, “G3000HXL”×1 and “G4000HXL”×1, available from Tosoh Corporation) with mono-dispersed polystyrene as a standard, under analytical conditions involving: a flow rate of 1.0 mL/min; an elution solvent of tetrahydrofuran; and a column temperature of 40° C.

Average Thickness of Film

The average thickness of the film was measured by using a spectroscopic ellipsometer (“M2000D”, available from J.A. Woollam Co.).

Synthesis of Polymer (A)

Silane monomers (monomers) used for the synthesis of the polymer (A) (siloxane polymer) are shown below.

Compounds (M-1) to (M-10): compounds represented by the following formulae (M-1) to (M-10)

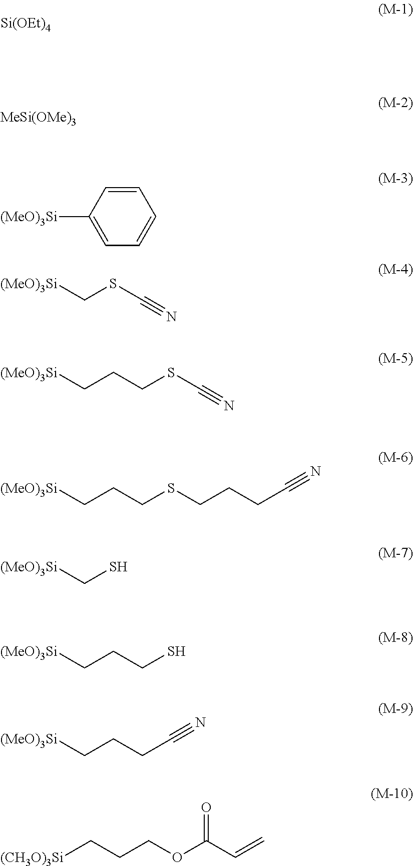

### Synthesis Example 1: (A-1) Siloxane Polymer

An aqueous oxalic acid solution was prepared by dissolving 1.61 g of oxalic acid in 24.11 g of water with heating. Into a reaction vessel, silane monomers and 25.40 g of methanol were charged. As the silane monomers, the compound represented by the chemical formula (M-1) and the compound represented by the chemical formula (M-3) were used with the mole fraction of 76/24 (mol %), and the total mass of the silane monomers was 48.88 g. A condenser and a dropping funnel including the aqueous oxalic acid solution prepared as described above were attached to the reaction vessel. Next, the reaction vessel was heated to 60° C. in an oil bath, and thereafter the aqueous oxalic acid solution was added dropwise over 10 min. The start time of the reaction was assumed to be the start time of the dropwise addition, and the reaction was allowed at 60° C. for 4 hrs. After completion of the reaction, the reaction vessel was cooled to 30° C. or lower. After 280 g of propylene glycol monomethyl ether acetate was added to the reaction vessel, a propylene glycol monomethyl ether acetate solution of a siloxane polymer (A-1) was obtained using an evaporator. The solid content concentration in the propylene glycol monomethyl ether acetate solution of the siloxane polymer (A-1) was 18.0% by mass. The siloxane polymer (A-1) had a weight average molecular weight (Mw) of 2,000.

### Synthesis Examples 2 to 15: (A-2) to (A-15) Siloxane Polymers

Siloxane polymers (A-2) to (A-15) were synthesized by a procedure similar to that of Synthesis Example 1 except that each monomer shown in Table 1 below was used in the amount shown in Table 1.

### Synthesis Example 16: (A-16) Siloxane Polymer

An aqueous solution was prepared by dissolving 3.45 g of triethylamine in 27.59 g of water with heating. Then, this aqueous solution and 34.48 g of methanol were charged into a reaction vessel, and a condenser and a dropping funnel including silane monomers and 34.48 g of methyl isobutyl ketone were attached to the reaction vessel. The silane monomers in the dropping funnel were provided with the compound (M-1), the compound (M-2) and the compound (M-3) with the mole fraction of 30/62/8 (mol %), and the total mass of the silane monomers was 17.62 g. Thereafter, the reaction vessel was heated to 60° C. in an oil bath, and a mix liquid of the adjusted silane monomers and methyl isobutyl ketone was added dropwise over 10 min. The start time of the reaction was assumed to be the termination time of the dropwise addition, and the reaction was allowed at 60° C. for 4 hrs. After completion of the reaction, the reaction vessel was cooled to 10° C. or lower to give a reaction mixture. Subsequently, an aqueous oxalic acid solution prepared by dissolving 7.24 g of oxalic acid in 96.21 g of water was cooled to 10° C. or below. Then, the reaction mixture was added dropwise addition to this aqueous oxalic acid solution and the mixture was stirred at 10° C. or below for 30 min. Next, 103.45 g of methyl isobutyl ketone was added thereto, and liquid-liquid extraction was carried out with a separatory funnel to give a methyl isobutyl ketone solution of a polysiloxane polymer (A-16). Thereto was further charged 310.35 g of propylene glycol monomethyl ether acetate, and methyl isobutyl ketone was removed with an evaporator to give a propylene glycol monomethyl ether acetate solution of the polysiloxane polymer (A-16). The solid content concentration in the propylene glycol monomethyl ether acetate solution of the polysiloxane polymer (A-16) was 18.2% by mass. The siloxane polymer (A-16) had a weight average molecular weight (Mw) of 1,900.

### Synthesis Examples 17 to 23: (A-17) to (A-23) Siloxane Polymers

Siloxane polymers (A-17) to (A-23) were synthesized by a similar procedure to that of Synthesis Example 16 except that each monomer shown in Table 1 below was used in the amount shown in Table 1.

TABLE 1

| | (A) | | | | | | | | | | | Solid content | |
|---|---|---|---|---|---|---|---|---|---|---|---|---|---|
| | Siloxane | (A) Amount of charged monomer (mol %) | | | | | | | | | | concentration | |
| | polymer | M-1 | M-2 | M-3 | M-4 | M-5 | M-6 | M-7 | M-8 | M-9 | M-10 | (% by mass) | Mw |
| Synthesis | A-1 | 76 | — | 24 | — | — | — | — | — | — | — | 18.0 | 2,000 |
| Example 1 | | | | | | | | | | | | | |
| Synthesis | A-2 | 76 | — | 14 | 10 | — | — | — | — | — | — | 17.5 | 2,100 |
| Example 2 | | | | | | | | | | | | | |
| Synthesis | A-3 | 76 | — | 10 | 14 | — | — | — | — | — | — | 18.6 | 2,200 |
| Example 3 | | | | | | | | | | | | | |
| Synthesis | A-4 | 74 | — | 6 | 20 | — | — | — | — | — | — | 17.9 | 2,050 |
| Example 4 | | | | | | | | | | | | | |
| Synthesis | A-5 | 76 | — | 14 | — | 10 | — | — | — | — | — | 18.6 | 2,100 |
| Example 5 | | | | | | | | | | | | | |
| Synthesis | A-6 | 76 | — | 10 | — | 14 | — | — | — | — | — | 17.9 | 2,150 |
| Example 6 | | | | | | | | | | | | | |
| Synthesis | A-7 | 74 | — | 6 | — | 20 | — | — | — | — | — | 18.1 | 2,100 |
| Example 7 | | | | | | | | | | | | | |
| Synthesis | A-8 | 80 | — | 10 | — | — | 10 | — | — | — | — | 18.0 | 2,200 |
| Example 8 | | | | | | | | | | | | | |
| Synthesis | A-9 | 76 | — | 10 | — | — | 14 | — | — | — | — | 17.9 | 2,100 |
| Example 9 | | | | | | | | | | | | | |
| Synthesis | A-10 | 76 | — | 20 | — | — | — | 4 | — | — | — | 18.2 | 2,200 |
| Example 10 | | | | | | | | | | | | | |
| Synthesis | A-11 | 76 | — | 14 | — | — | — | 10 | — | — | — | 18.8 | 2,000 |
| Example 11 | | | | | | | | | | | | | |
| Synthesis | A-12 | 76 | — | 14 | — | — | — | — | 10 | — | — | 18.0 | 2,200 |
| Example 12 | | | | | | | | | | | | | |
| Synthesis | A-13 | 76 | — | 10 | — | — | — | — | 14 | — | — | 18.1 | 2,200 |
| Example 13 | | | | | | | | | | | | | |
| Synthesis | A-14 | 76 | — | 14 | — | — | — | — | — | 10 | — | 18.3 | 2,250 |
| Example 14 | | | | | | | | | | | | | |
| Synthesis | A-15 | 76 | — | 10 | — | — | — | — | — | 14 | — | 18.0 | 2,200 |
| Example 15 | | | | | | | | | | | | | |
| Synthesis | A-16 | 30 | 62 | 8 | — | — | — | — | — | — | — | 18.2 | 1,900 |
| Example 16 | | | | | | | | | | | | | |
| Synthesis | A-17 | 15 | — | 8 | — | — | — | — | — | — | 77 | 17.9 | 2,150 |
| Example 17 | | | | | | | | | | | | | |
| Synthesis | A-18 | — | — | 8 | 15 | — | — | — | — | — | 77 | 18.6 | 2,000 |
| Example 18 | | | | | | | | | | | | | |
| Synthesis | A-19 | — | — | 8 | — | 15 | — | — | — | — | 77 | 17.9 | 2,100 |
| Example 19 | | | | | | | | | | | | | |
| Synthesis | A-20 | — | — | 8 | — | — | 15 | — | — | — | 77 | 18.6 | 2,150 |
| Example 20 | | | | | | | | | | | | | |
| Synthesis | A-21 | — | — | 8 | — | — | — | 15 | — | — | 77 | 17.9 | 2,050 |
| Example 21 | | | | | | | | | | | | | |
| Synthesis | A-22 | — | — | 8 | — | — | — | — | 15 | — | 77 | 18.1 | 2,200 |
| Example 22 | | | | | | | | | | | | | |
| Synthesis | A-23 | — | — | 8 | — | — | — | — | — | 15 | 77 | 18.0 | 2,100 |
| Example 23 | | | | | | | | | | | | | |

Preparation of Film-Forming Material for a Resist Process

Components other than the polymer component (A) used in the preparation of the film-forming materials for a resist process are presented below.

(B) Organic Solvent

B-1: propylene glycol monomethyl ether acetate

(C) Additive

C-1: compound shown below

C-2: compound shown below

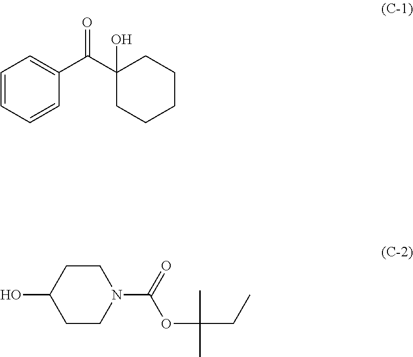

(D) Crosslinking Agent

D-1: compound shown below

D-2: compound shown below

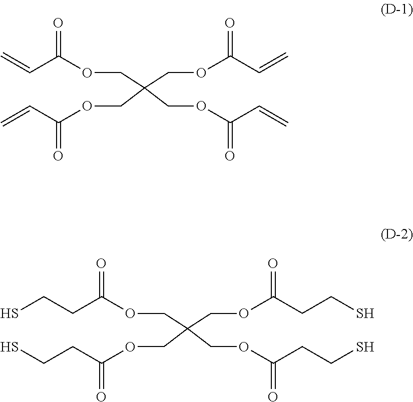 [SMILES: C=CC(=O)OCC(COC(=O)C=C)(COC(=O)C=C)COC(=O)C=C ; O=C(CCS)OCC(COC(=O)CCS)(COC(=O)CCS)COC(=O)CCS]

### Example 1

As shown in Table 2, 2.0 parts by mass of the siloxane polymer (A-2) obtained in Synthesis Example 2 was dissolved in 97.5 parts by mass of the organic solvent (B-1), and thereafter 0.5 parts by mass of water (E) were added to the mixture. This solution was filtered through a filter having a pore size of 0.2 μm to give a film-forming material for a resist process (J-1).

### Examples 2 to 16 and Comparative Examples 1 to 2

Film-forming materials for a resist process (J-2) to (J-16) and (j-1) to (j-2) were prepared by a similar procedure to that of Example 1 except that each component was used at the proportion shown in Table 2.

TABLE 2

| | Material | | | | | | | | | | | |
|---|---|---|---|---|---|---|---|---|---|---|---|---|
| | for | (A) Siloxane polymer | | | | (B) Organic | | (C) | | (D) Crosslinking | | (E) |
| | silicon- | component | | | | solvent | | Additive | | agent | | Water |
| | containing | | amount | | amount | | amount | | amount | | amount | amount |
| | film | | (parts | | (parts | | (parts | | (parts | | (parts | (parts |
| | formation | type | by mass) | type | by mass) | type | by mass) | type | by mass) | type | by mass) | by mass) |
| Example 1 | J-1 | A-2 | 2.0 | — | — | B-1 | 97.5 | — | — | — | — | 0.5 |
| Example 2 | J-2 | A-3 | 2.0 | — | — | B-1 | 97.5 | — | — | — | — | 0.5 |
| Example 3 | J-3 | A-4 | 2.0 | — | — | B-1 | 97.5 | — | — | — | — | 0.5 |
| Example 4 | J-4 | A-5 | 2.0 | — | — | B-1 | 97.5 | — | — | — | — | 0.5 |
| Example 5 | J-5 | A-6 | 2.0 | — | — | B-1 | 97.5 | — | — | — | — | 0.5 |
| Example 6 | J-6 | A-7 | 2.0 | — | — | B-1 | 97.5 | — | — | — | — | 0.5 |
| Example 7 | J-7 | A-8 | 2.0 | — | — | B-1 | 97.5 | — | — | — | — | 0.5 |
| Example 8 | J-8 | A-9 | 2.0 | — | — | B-1 | 97.5 | — | — | — | — | 0.5 |
| Example 9 | J-9 | A-10 | 1.0 | A-14 | 1.0 | B-1 | 97.5 | — | — | — | — | 0.5 |
| Example 10 | J-10 | A-10 | 1.0 | A-15 | 1.0 | B-1 | 97.5 | — | — | — | — | 0.5 |
| Example 11 | J-11 | A-11 | 1.0 | A-14 | 1.0 | B-1 | 97.5 | — | — | — | — | 0.5 |
| Example 12 | J-12 | A-11 | 1.0 | A-15 | 1.0 | B-1 | 97.5 | — | — | — | — | 0.5 |
| Example 13 | J-13 | A-12 | 1.0 | A-14 | 1.0 | B-1 | 97.5 | — | — | — | — | 0.5 |
| Example 14 | J-14 | A-12 | 1.0 | A-15 | 1.0 | B-1 | 97.5 | — | — | — | — | 0.5 |
| Example 15 | J-15 | A-13 | 1.0 | A-14 | 1.0 | B-1 | 97.5 | — | — | — | — | 0.5 |
| Example 16 | J-16 | A-13 | 1.0 | A-15 | 1.0 | B-1 | 97.5 | — | — | — | — | 0.5 |
| Comparative | j-1 | A-1 | 2.0 | — | — | B-1 | 97.5 | — | — | — | — | 0.5 |
| Example 1 | | | | | | | | | | | | |
| Comparative | j-2 | A-14 | 2.0 | — | — | B-1 | 97.5 | — | — | — | — | 0.5 |
| Example 2 | | | | | | | | | | | | |

### Example 17

As shown in Table 3, 2.8 parts by mass of the siloxane polymer (A-18) obtained in Synthesis Example 18, 0.1 parts by mass of the additive (C-1) and 0.6 parts by mass of the crosslinking agent (D-1) were dissolved in 96.0 parts by mass of the organic solvent (B-1) (also including the solvent (B-1) contained in the solution of the polymer component (A)), and thereafter 0.5 parts by mass of water (E) were added to the mixture. This solution was filtered through a filter having a pore size of 0.2 μm to give a film-forming material for a resist process (J-17).

### Examples 18 to 26 and Comparative Examples 3 to 5

Film-forming materials for a resist process (J-17) to (J-26), and (j-3) to (j-5) were prepared by a similar procedure to that of Example 17 except that each component was used at the proportion shown in Table 3.

TABLE 3

| | Material | | | | | | | | | | | |
|---|---|---|---|---|---|---|---|---|---|---|---|---|
| | for | (A) Siloxane | | | | (B) Organic | | (C) | | (D) Crosslinking | | (E) |
| | silicon- | polymer component | | | | solvent | | Additive | | agent | | Water |
| | containing | | amount | | amount | | amount | | amount | | amount | amount |
| | film | | (parts | | (parts | | (parts | | (parts | | (parts | (parts |
| | formation | type | by mass) | type | by mass) | type | by mass) | type | by mass) | type | by mass) | by mass) |
| Example 17 | J-17 | A-18 | 2.8 | — | — | B-1 | 96.0 | C-1 | 0.1 | D-1 | 0.6 | 0.5 |
| Example 18 | J-18 | A-19 | 2.8 | — | — | B-1 | 96.0 | C-1 | 0.1 | D-1 | 0.6 | 0.5 |
| Example 19 | J-19 | A-20 | 2.8 | — | — | B-1 | 96.0 | C-1 | 0.1 | D-1 | 0.6 | 0.5 |
| Example 20 | J-20 | A-21 | 1.4 | A-23 | 1.4 | B-1 | 96.0 | C-1 | 0.1 | D-1 | 0.6 | 0.5 |
| Example 21 | J-21 | A-22 | 1.4 | A-23 | 1.4 | B-1 | 96.0 | C-1 | 0.1 | D-1 | 0.6 | 0.5 |
| Example 22 | J-22 | A-18 | 2.8 | — | — | B-1 | 96.0 | C-2 | 0.1 | D-2 | 0.6 | 0.5 |
| Example 23 | J-23 | A-19 | 2.8 | — | — | B-1 | 96.0 | C-2 | 0.1 | D-2 | 0.6 | 0.5 |
| Example 24 | J-24 | A-20 | 2.8 | — | — | B-1 | 96.0 | C-2 | 0.1 | D-2 | 0.6 | 0.5 |
| Example 25 | J-25 | A-21 | 1.4 | A-23 | 1.4 | B-1 | 96.0 | C-2 | 0.1 | D-2 | 0.6 | 0.5 |
| Example 26 | J-26 | A-22 | 1.4 | A-23 | 1.4 | B-1 | 96.0 | C-2 | 0.1 | D-2 | 0.6 | 0.5 |
| Comparative | j-3 | A-16 | 3.4 | — | — | B-1 | 95.4 | C-1 | 0.1 | D-1 | 0.6 | 0.5 |
| Example 3 | | | | | | | | | | | | |
| Comparative | j-4 | A-17 | 3.0 | — | — | B-1 | 95.8 | C-1 | 0.1 | D-1 | 0.6 | 0.5 |
| Example 4 | | | | | | | | | | | | |
| Comparative | j-5 | A-23 | 3.0 | — | — | B-1 | 95.8 | C-1 | 0.1 | D-1 | 0.6 | 0.5 |
| Example 5 | | | | | | | | | | | | |

### Formation of Silicon-Containing Film

Each film-forming material for a resist process obtained as described above was applied onto a silicon wafer (substrate) by spin-coating using a spin coater (“CLEAN TRACK ACT12”, available from Tokyo Electron Limited). The coating film thus obtained was subjected to a heat treatment on a hot plate at 220° C. for 60 sec, and then cooled at 23° C. for 60 sec to give a substrate on which the silicon-containing film having an average thickness of 30 nm was formed.

### Evaluations

Evaluations of the following items were made on the silicon-containing films formed as described above, by methods described below. The results of the evaluations are shown in Tables 4 and 5 below.

CF₄ Gas Etching Easiness

The silicon-containing film formed as described above was subjected to a treatment by using an etching apparatus (“TACTRAS”, available from Tokyo Electron Limited), under conditions involving CF₄=60 sccm, PRESS.=50 MT, HF RF=500 W, LF RF=100 W, DCS=300 V, RDC=50%, 30 sec. The etching rate (Å/sec) was calculated from average film thicknesses before and after the treatment. The evaluation was made based on the etching rate: “A” (extremely favorable) in the case of being no less than 11.0; “B” (favorable) in the case of being less than 11.0 and no less than 10.0; “C” (somewhat favorable) in the case of being less than 10.0 and no less than 8.5; “D” (somewhat unfavorable) in the case of being no less than 8.0 and less than 8.5; and “E” (unfavorable) in the case of being less than 8.0.

Oxygen Gas Etching Resistance

The silicon-containing film formed as described above was subjected to a treatment by using an etching apparatus (“TACTRAS”, available from Tokyo Electron Limited), under conditions involving O₂=400 sccm, PRESS.=45 MT, HF RF=400 W, LF RF=0 W, DCS=0 V, RDC=50%, 60 sec. The etching rate (Å/sec) was calculated from average film thicknesses before and after the treatment. The evaluation was made based on the etching rate: “A” (extremely favorable) in the case of being less than 1.0; “B” (favorable) in the case of being no less than 1.0 and less than 2.0; “C” (somewhat favorable) in the case of being no less than 2.0 and less than 3.5; and “D” (“unfavorable”) in the case of being no less than 3.5.

Solvent Resistance

The substrate on which the silicon-containing film was formed which was obtained as described above was immersed in cyclohexanone at room temperature for 10 sec. Average thicknesses of the silicon-containing film before and after the immersion were measured by using a spectroscopic ellipsometer. When the average thickness before the immersion is denoted by T₀, and the average thickness after the immersion is denoted by T₁, the rate of change (%) in film thickness due to the immersion in the solvent was determined according to the following equation:

rate of change in film thickness (%)=|T₁−T₀|×100/T₀.

The evaluation of the solvent resistance was made based on the rate of change in film thickness: “A” (favorable) in the case of being less than 1%, “B” (“unfavorable”) in the case of being no less than 1%.

Substrate Reflectance

The refractive index parameter (n) and the extinction coefficient (k) of the silicon-containing film formed as described above, a composition for underlayer film formation (“NFC HM8006”, available from JSR Corporation) and a resist material (“ARF AR2772JN”, available from JSR Corporation) were each measured with a high-speed spectroscopic ellipsometer (“M-2000D”, available from J.A. Woollam Co.). The measurements were employed to determine the substrate reflectance of the film provided by laminating the resist material/the silicon-containing film/the composition for underlayer film formation under a condition involving: NA of 1.3; and Dipole by using a simulation soft (“Prolith”, available from KLA-Tencor Corp.). The evaluation of the substrate reflectance was made: “A” in the case of being no greater than 1%; and “B” in the case of being greater than 1%.

Removability with Acidic Liquid

The silicon-containing film formed as described above was immersed for 15 min in an acidic removal liquid (aqueous mixed solution of 96% sulfuric acid: 30% aqueous hydrogen peroxide=3:1) which had been heated to 110° C. Average thicknesses of the silicon-containing film before and after the immersion were measured. The evaluation of the acidic liquid removability (removability with an acidic liquid) was made based on the removal rate (n/min) of the silicon-containing film formed on the substrate: “A” (extremely favorable) in the case of being no less than 1.5; “B” (favorable) in the case of being no less than 0.8 and less than 1.5; “C” (somewhat favorable) in the case of being no less than 0.3 and less than 0.8; and “D” (unfavorable) in the case of being less than 0.3.

### Results

The results of the evaluations of each item of the CF₄ gas etching easiness, the oxygen gas etching resistance, the solvent resistance and the substrate reflectance on the film-forming materials for a resist process of Examples 1 to 16, and Comparative Examples 1 to 2 are shown in Table 4. Also, the results of the evaluations of each item of the acidic liquid removability, the CF₄ gas etching easiness, the oxygen gas etching resistance, the solvent resistance and the substrate reflectance on the film-forming materials for a resist process of Examples 17 to 26, Comparative Examples 3 to 5 are shown in Table 5.

TABLE 4

Evaluations

| | CF₄ gas | O₂ gas | | |
|---|---|---|---|---|
| | etching | etching | Solvent | Substrate |
| | easiness | resistance | resistance | reflectance |
| Example 1 | A | A | A | A |
| Example 2 | A | A | A | A |
| Example 3 | A | A | A | A |
| Example 4 | A | A | A | A |
| Example 5 | A | A | A | A |
| Example 6 | A | A | A | A |
| Example 7 | A | A | A | A |
| Example 8 | A | A | A | A |
| Example 9 | B | B | A | A |
| Example 10 | B | B | A | A |
| Example 11 | A | A | A | A |
| Example 12 | A | A | A | A |
| Example 13 | A | A | A | A |
| Example 14 | A | A | A | A |
| Example 15 | A | A | A | A |
| Example 16 | A | A | A | A |
| Comparative | D | B | A | A |
| Example 1 | | | | |
| Comparative | C | B | A | A |
| Example 2 | | | | |

TABLE 5

| | Evaluations | | | | |
|---|---|---|---|---|---|
| | Acidic | CF₄ gas | O₂ gas | | |
| | liquid | etching | etching | Solvent | Substrate |
| | removability | easiness | resistance | resistance | reflectance |
| Example 17 | A | C | C | A | A |
| Example 18 | A | C | C | A | A |
| Example 19 | A | C | C | A | A |
| Example 20 | A | C | C | A | A |
| Example 21 | A | C | C | A | A |
| Example 22 | A | C | C | A | A |
| Example 23 | A | C | C | A | A |
| Example 24 | A | C | C | A | A |
| Example 25 | A | C | C | A | A |
| Example 26 | A | C | C | A | A |
| Comparative | D | C | B | A | A |
| Example 3 | | | | | |
| Comparative | A | D | D | A | A |
| Example 4 | | | | | |
| Comparative | A | D | D | A | A |
| Example 5 | | | | | |

### DISCUSSION

The results shown in Table 4 reveal that the film-forming materials of Examples 1 to 16 were capable of forming silicon-containing films having the CF₄ gas etching easiness and oxygen etching resistance being superior (evaluation: A or B), as well as favorable solvent resistance and low substrate reflectance. In addition, the results shown in Table 5 reveal that the film-forming materials of Examples 17 to 26 were capable of forming silicon-containing films which exhibited all the acidic liquid removability, the CF₄ gas etching easiness and the oxygen gas etching resistance rated as being C or more favorable, with favorable solvent resistance and low substrate reflectance.

The film-forming material for a resist process and the pattern-forming method of the embodiments of the present invention can be suitably used for manufacture of semiconductor devices, and the like.

Obviously, numerous modifications and variations of the present invention are possible in light of the above teachings. It is therefore to be understood that within the scope of the appended claims, the invention may be practiced otherwise than as specifically described herein.

1. A film-forming material for a resist process, comprising:
a siloxane polymer component comprising at least two selected from a sulfur atom, a nitrogen atom, a boron atom, a phosphorus atom and a combination thereof; and
an organic solvent.

2. The film-forming material according to claim 1, wherein the siloxane polymer component has a formulation represented by formula (1): 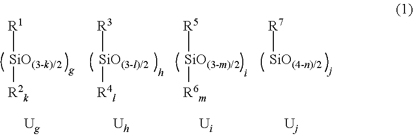
wherein, in the formula (1),
R¹ represents a monovalent organic group comprising at least one of a sulfur atom and a nitrogen atom;
R² represents a monovalent organic group comprising at least one of a sulfur atom and a nitrogen atom, a hydrogen atom, a hydroxy group, or a substituted or unsubstituted hydrocarbon group having 1 to 20 carbon atoms;
k is 0 or 1;
R³ represents a monovalent organic group comprising an ethylenic unsaturated double bond;
R⁴ represents a monovalent organic group comprising an ethylenic unsaturated double bond, a hydrogen atom, a hydroxy group, or a substituted or unsubstituted hydrocarbon group having 1 to 20 carbon atoms;
l is 0 or 1;
R⁵ represents a non-crosslinkable monovalent organic group comprising a photoabsorptive group comprising neither a sulfur atom nor a nitrogen atom;
R⁶ represents a non-crosslinkable monovalent organic group comprising a photoabsorptive group comprising neither a sulfur atom nor a nitrogen atom, a hydrogen atom, a hydroxy group, or a substituted or unsubstituted non-crosslinkable monovalent hydrocarbon group having 1 to 20 carbon atoms;
m is 0 or 1;
R⁷ represents a substituted or unsubstituted non-crosslinkable and non-photoabsorptive monovalent aliphatic hydrocarbon group comprising neither a sulfur atom nor a nitrogen atom, or a substituted or unsubstituted non-crosslinkable and non-photoabsorptive monovalent alicyclic hydrocarbon group comprising neither a sulfur atom nor a nitrogen atom;
n is an integer of 0 to 2;
g denotes a mole fraction of a structural unit U_{g} with respect to total structural units comprised in the siloxane polymer component;
h denotes a mole fraction of a structural unit Uₕ with respect to total structural units comprised in the siloxane polymer component;
i denotes a mole fraction of a structural unit Uᵢ with respect to total structural units comprised in the siloxane polymer component; and
j denotes a mole fraction of a structural unit Uⱼ with respect to total structural units comprised in the siloxane polymer component, wherein
inequalities: 0<g<1; 0≤h<1; 0≤i<1; 0≤j<1; and g+h+i+j≤1 are satisfied, and
in a case in which the structural unit U_{g} does not comprise a structural unit U_{g1}, the structural unit U_{g} comprises a structural unit U_{g2}, or both a structural unit U_{g3-1} and a structural unit U_{g3-2}, provided that:
the structural unit U_{g}i is the structural unit U_{g} in which R¹ or R² represents a monovalent organic group comprising a sulfur atom and a nitrogen atom;
the structural unit U_{g2} is the structural unit U_{g} in which k is 1; R¹ represents a monovalent organic group comprising a sulfur atom and no nitrogen atom; and R² represents a monovalent organic group comprising a nitrogen atom and no sulfur atom;
the structural unit U_{g3-1} is the structural unit U_{g} in which R¹ represents a monovalent organic group comprising a sulfur atom and no nitrogen atom, wherein in a case in which k is 1, R² represents a group other than a monovalent organic group comprising a nitrogen atom; and
the structural unit U_{g3-2} is the structural unit U_{g} in which R¹ represents a monovalent organic group comprising a nitrogen atom and no sulfur atom, wherein in a case in which k is 1, R² represents a group other than a monovalent organic group comprising a sulfur atom.

3. The film-forming material according to claim 2, wherein h in the formula (1) satisfies an inequality: 0<h<1.

4. The film-forming material according to claim 2, wherein i in the formula (1) satisfies an inequality: 0<i<1.

5. The film-forming material according to claim 2, wherein j in the formula (1) satisfies an inequality: 0<j<1.

6. The film-forming material according to claim 2, wherein
in the formula (1), R¹ and R² each comprise a sulfide group, a polysulfide group, a sulfoxide group, a sulfonyl group, a sulfanyl group, a cyano group, a thiocyanate group, an isothiocyanate group, a thioisocyanate group or a combination thereof.

7. The film-forming material according to claim 2, wherein,
in the formula (1), number of the carbon atoms in each of R¹ and R² is from 1 to 6.

8. The film-forming material according to claim 1, which is suitable for a multilayer resist process.

9. A pattern-forming method comprising:
applying the film-forming material according to claim 1 onto a substrate to form a silicon-containing film;
forming a pattern using the silicon-containing film as a mask; and
removing the silicon-containing film.

10. The pattern-forming method according to claim 9, further comprising:
forming a resist pattern directly or indirectly on an upper side of the silicon-containing film; and
etching the silicon-containing film using the resist pattern as a mask.

11. The pattern-forming method according to claim 9, further comprising forming a resist underlayer film on the substrate, before forming the silicon-containing film.

12. The pattern-forming method according to claim 9, wherein the removing of the silicon-containing film comprises bringing an acidic liquid into contact with the silicon-containing film.
